(19) United States
(12) Patent Application Publication
(10) Pub. No.: US 2015/0214197 A1
(43) Pub. Date: Jul. 30, 2015

(54) LIGHT-EMITTING DEVICE

(71) Applicant: Panasonic Intellectual Property Management Co., Ltd., Osaka (JP)

(72) Inventors: HIDEKI OHMAE, Hyogo (JP); JUNICHI HIBINO, Osaka (JP); ATSUSHI YAMADA, Osaka (JP); DAISUKE UEDA, Osaka (JP)

(21) Appl. No.: 14/675,748

(22) Filed: Apr. 1, 2015

Related U.S. Application Data
(63) Continuation of application No. PCT/JP2014/003897, filed on Jul. 24, 2014.

(30) Foreign Application Priority Data
Aug. 6, 2013 (JP) 2013-163679
Jul. 9, 2014 (JP) 2014-141764

(51) Int. Cl. H01L 25/13; F21K 99/00; H01L 33/38; F21V 23/00

(52) U.S. Cl. CPC H01L 25/13; F21V 23/002; F21K 9/30; H01L 33/387; F21Y 2101/02

(57) ABSTRACT

A light-emitting device includes: a plurality of LED chips each having a light-emitting region, and a first electrode and a second electrode that are electrically connected to light-emitting region; a plurality of substrates each being provided on each of the plurality of LED chips; a plurality of through-holes each penetrating through each of the plurality of substrates; and, a plurality of wires each passing through a first through-hole penetrated through a first substrate of the plurality of the substrates and a second through-hole penetrated through a second substrate adjacent to the first substrate. The one of the plurality of the wires is electrically connected the first electrode or the second electrode of a first LED chip corresponding to the first substrate, to the first electrode or the second electrode of a second LED chip corresponding to the second substrate.

### BACKGROUND

1. Technical Field

The present disclosure relates to a light-emitting device, especially a flexible or stretchable light-emitting device.

2. Description of the Related Art

A display device that is provided with a large number of regularly disposed light-emitting elements and that displays predetermined characters, figures, symbols, etc. by blinking the light-emitting elements appropriately is known.

In this display device, thin-film-shaped conductors are disposed in a grid manner, one of columns and rows of the conductors serves as an anode and the other serves as a cathode, and the light-emitting elements are provided at intersections of the columns and the rows of the conductors.

Japanese Unexamined Patent Application Publication No. 8-054840 is an example of related art.

### SUMMARY

In one general aspect, the techniques disclosed here feature a light-emitting device includes: a plurality of LED chips each having a light-emitting region, and a first electrode and a second electrode that are electrically connected to the light-emitting region; a plurality of substrates each being provided on each of the plurality of LED chips; a plurality of through-holes each penetrating through each of the plurality of substrates; and, a plurality of wires each passing through a first through-hole penetrated through a first substrate of the plurality of the substrates and a second through-hole penetrated through a second substrate adjacent to the first substrate. The one of the plurality of the wires is electrically connected the first electrode or the second electrode of a first LED chip corresponding to the first substrate, to the first electrode or the second electrode of a second LED chip corresponding to the second substrate.

According to the light-emitting device according to one aspect of the present disclosure, it is possible to reduce a load applied to a connection point between a wire and the light-emitting device.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a conceptual diagram illustrating a configuration of an LED array including a light-emitting device according to Embodiment 1;

FIG. 2 is an electric circuit diagram of the light-emitting device according to Embodiment 1;

FIG. 3 is a top view illustrating a configuration of an LED chip according to Embodiment 1;

FIG. 4 is a top view illustrating a configuration of an LED chip according to Embodiment 1;

FIG. 5 is a view schematically illustrating steps for producing the light-emitting device according to Embodiment 1;

FIG. 6 is a view schematically illustrating steps for producing the light-emitting device according to Embodiment 1;

FIG. 7 is a view schematically illustrating steps for producing the light-emitting device according to Embodiment 1;

FIG. 8 is a top view illustrating steps for producing an LED chip according to Embodiment 1;

FIG. 9 is a top view illustrating steps for producing an LED chip according to Embodiment 1;

FIG. 10 is a top view illustrating steps for producing an LED chip according to Embodiment 1;

FIG. 11 is a top view illustrating steps for producing an LED chip according to Embodiment 1;

FIG. 12 is a top view illustrating steps for producing an LED chip according to Embodiment 1;

FIG. 13 is a top view illustrating a configuration of an LED chip according to Embodiment 1;

FIG. 14 is a top view illustrating a configuration of an LED chip having a plurality of through-holes having different diameters;

FIG. 15 is a view schematically illustrating step for producing the light-emitting device according to Embodiment 1;

FIG. 16A is a schematic view corresponding to FIG. 15;

FIG. 16B is an enlarged view of a part 70 encircled by a broken line in FIG. 16A;

FIG. 17 is a cross-sectional view illustrating a configuration of the light-emitting device according to Embodiment 1;

FIG. 18 is a cross-sectional view illustrating a configuration of the light-emitting device according to Embodiment 1;

FIG. 19 is a cross-sectional view illustrating a configuration of a light-emitting device according to a modification of Embodiment 1;

FIG. 20 is a cross-sectional view illustrating a configuration of a light-emitting device according to Embodiment 2;

FIG. 21 is a cross-sectional view illustrating a configuration of a light-emitting device according to Embodiment 3;

FIG. 22 is a cross-sectional view illustrating a configuration of a light-emitting device according to Embodiment 3;

FIG. 23 is a cross-sectional view illustrating a configuration of a light-emitting device according to Embodiment 4;

FIG. 24 is a cross-sectional view illustrating a configuration of a light-emitting device according to Embodiment 4;

FIG. 25 is a cross-sectional view illustrating a configuration of a light-emitting device according to a modification of Embodiment 4;

FIG. 26 is a cross-sectional view illustrating a configuration of a light-emitting device according to a modification of Embodiment 4;

FIG. 27 is a top view illustrating a configuration of a light-emitting device according to a modification of Embodiment 4;

FIG. 28 is a cross-sectional view illustrating a configuration of a light-emitting device according to Embodiment 5;

FIG. 29 is a cross-sectional view illustrating a configuration of a light-emitting device according to Embodiment 5;

FIG. 30 is a cross-sectional view illustrating a configuration of a light-emitting device according to Embodiment 5;

FIG. 31 is a cross-sectional view illustrating a configuration of a light-emitting device according to a modification of Embodiment 5;

FIG. 32 is a cross-sectional view illustrating a configuration of a light-emitting device according to a modification of Embodiment 5; and

FIG. 33 is a cross-sectional view illustrating a configuration of a light-emitting device according to a modification of Embodiment 5.

### DETAILED DESCRIPTION

Embodiments are described in detail below with reference to the drawings as appropriate. Note, however, that unnecessarily detailed description may be omitted. For example, detailed description of well-known matters and overlapping description of substantially identical arrangements may be omitted. This is to prevent the following description from becoming unnecessarily redundant, thereby promoting the understanding of a person skilled in the art.

According to the above conventional display device, in a case where a wiring board is warped in a curved shape, a load is likely to be applied to a connection point between an electrode and a wire in a light-emitting device. As a result of the load applied to the connection point between the wire and the electrode, the electrode provided in the light-emitting device is undesirably peeled off.

The present disclosure prevents breakage of a light-emitting device by reducing a bad applied between a wire and the light-emitting device.

A light-emitting device according to one aspect of the present disclosure includes: a plurality of LED chips each having a light-emitting region, and a first electrode and a second electrode that are electrically connected to the light-emitting region; a plurality of substrates each corresponding each of the plurality of LED chips, each of the plurality of the LED chips being provided above each of the plurality of substrates; a plurality of through-holes each penetrating through each of the plurality of substrates; and a plurality of wires each made of a conductive re material. One of the plurality of the wires passes through a first through-hole penetrated through a first substrate of the plurality of the substrates and a second through-hole penetrated through a second substrate adjacent to the first substrate. The one of the plurality of the wires electrically connects the first electrode or the second electrode of a first LED chip corresponding to the first substrate, to the first electrode or the second electrode of a second LED chip corresponding to the second substrate.

According to this arrangement, the wire penetrates the through-hole and is then connected to the electrode. This restricts a movable region of the wire. It is therefore possible to provide a light-emitting device that suppresses a mechanical load applied to a connection point between a wire and an electrode and that has high mechanical strength.

In the one aspect, at least part of a side surface of each of the plurality of the wires may be not in contact with an inner surface of the first through-hole and an inner surface of the second through-hole.

According to this arrangement, at least part of the side surface of the wire is not in contact with the inner surface of the through-hole and is movable inside the through-hole. It is therefore possible to suppress a mechanical load applied to a connection point between the wire and the electrode.

In the one aspect, a first diameter of the through-hole on one of two surfaces of the substrate on which the first electrode and the second electrode are provided may be smaller than a second diameter of the through-hole on the other one of the two surfaces of the substrate on which the first electrode and the second electrode are not provided.

According to this arrangement, a movable range of the wire is restricted. It is therefore possible to more effectively suppress a mechanical load applied to a connection point between the wire and the electrode.

In the one aspect, a first diameter of the through-hole on one of two surfaces of the substrate on which the first electrode and the second electrode are provided may be larger than a second diameter of the through-hole on the other one of the two surfaces of the substrate on which the first electrode and the second electrode are not provided.

According to this arrangement, a region where the wire tends to come into contact with the through-hole (the side where the diameter is smaller) is located away from the electrode to which the wire is connected. This makes it possible to suppress damage to the wire caused by contact with the through-hole.

In the one aspect, in a cross-sectional view, the shape of the through-hole in each of the plurality of substrates may be tapered in the thickness direction of each of the plurality of substrates.

According to this arrangement, the wire is disposed in the through-hole along this warped portion, so that a mechanical load applied to the wire is small. Therefore, the wire passing through the through-hole can be easily connected to the electrode.

In the one aspect, each of the plurality of the wires electrically may connect the first electrode or the second electrode of the first LED chip, to the first electrode or the second electrode of the second LED chip, by a conductive material.

According to this arrangement, the wire can be fixed to the first electrode and the second electrode, and the wire can be electrically connected to the first electrode and the second electrode with high accuracy.

In the one aspect, the plurality of substrates may include insulators.

According to this arrangement, the LED chips can be mounted on the substrate after running the wire through the through-hole formed in the insulating substrate.

In the one aspect, the light-emitting device may further include a plurality of insulating wires. Moreover, one of the plurality of the insulating wires may pass through the first through-hole and the second through-hole. The plurality of the insulating wires may have higher rigidity than the plurality of the wires.

In the one aspect, the light-emitting device may further include a plurality of insulating wires. Moreover, the first substrate may have a third through-hole other than the first through-hole and the second substrate may have a fourth through-hole other than the second through-hole. One of the plurality of the insulating wires may pass through the third through-hole penetrated through the first substrate and the fourth through-hole penetrated through the second substrate. The plurality of the insulating wires may have higher rigidity than the plurality of the wires.

According to this arrangement, since the rigidity of the insulating wire is higher than that of the wire, it is possible to reduce a mechanical load applied to the wire when the light-emitting device is deformed (e.g., warped).

A light-emitting device according to one aspect of the present disclosure include: a plurality of LED chips each having a light-emitting region, a first electrode and a second electrode that are electrically connected to the light-emitting region, and a substrate in or on which the lighting-emitting region is provided; a plurality of through-holes each penetrating through each of the plurality of the substrates; and a plurality of wires each made of a threadlike conductive wire material. One of the plurality of the wires may pass through a first through-hole penetrated through a first LED chip of the plurality of the LED chips and a second through-hole penetrated through a second LED chip of the plurality of the LED chips, the second LED chip being adjacent to the first LED chip, and electrically connects the first electrode or the second electrode of the first LED chip of the plurality of the LED chips to the first electrode or the second electrode of the second LED chip of the plurality of the LED chips.

According to this arrangement, even in a case where the light-emitting device is an LED device in which a light-emitting region is formed on a substrate, a wire penetrates a through-hole formed through the substrate. This restricts a movable region of the wire, thereby suppressing a mechanical load applied to a connection point between the wire and an electrode.

In the one aspect, the first electrode and the second electrode may be directly provided on the substrate.

According to this arrangement, even in a case where a substrate of an LED chip is itself a light-emitting region, a wire penetrates a through-hole formed through the substrate. This restricts a movable region of the wire, thereby suppressing a mechanical load applied to a connection point between the wire and an electrode.

In the one aspect, each of the plurality of LED chips may include a multi-layer body in which an n-type semiconductor layer and a p-type semiconductor layer sandwiches the light-emitting region. The first electrode may be an anode electrode that is electrically connected to the p-type semiconductor layer. The second electrode may be a cathode electrode that is electrically connected to the n-type semiconductor layer. The through-hole penetrates through both surfaces of the substrate at a position where the through-hole is provided.

In the one aspect, the substrate may include an n-type semiconductor layer. A p-type semiconductor layer may be stacked on the substrate. The first electrode may be an anode electrode that is electrically connected to the p-type semiconductor layer. The second electrode may be a cathode electrode that is electrically connected to the n-type semiconductor layer. The through-hole may penetrate through both surfaces of the substrate at a position where the through-hole is provided.

According to this arrangement, the wire penetrates the through-hole and is then connected to the electrode. This restricts a movable region of the wire. It is therefore possible to suppress a mechanical load applied to a connection point between the wire and the electrode.

In the one aspect, at least part of a side surface of each of the plurality of the wires may be not in contact with the inner surface of the first through-hole and an inner surface of the second through-hole.

According to this arrangement, at least part of the side surface of the wire is not in contact with the inner surface of the through-hole and is movable inside the through-hole. It is therefore possible to suppress a mechanical load applied to a connection point between the wire and the electrode.

In the one aspect, a first diameter of the through-hole on one of two surfaces of the substrate on which the first electrode and the second electrode are provided may be smaller than a second diameter of the through-hole on the other one of the two surfaces of the substrate on which the first electrode and the second electrode are not provided.

According to this arrangement, a movable range of the wire is restricted. It is therefore possible to more effectively suppress a mechanical load applied to a connection point between the wire and the electrode.

In the one aspect, a first diameter of the through-hole on one of two surfaces of the substrate on which the first electrode and the second electrode are provided may be larger than a second diameter of the through-hole on the other one of the two surfaces of the substrate on which the first electrode and the second electrode are not provided.

According to this arrangement, a region where the wire tends to come into contact with the through-hole (the side where the diameter is smaller) is located away from the electrode to which the wire is connected. This makes it possible to suppress damage to the wire caused by contact with the through-hole.

In the one aspect, in a cross-sectional view, the shape of the through-hole in each of the plurality of substrates may be tapered in the thickness direction of each of the plurality of substrates.

According to this arrangement, the wire is disposed in the through-hole along this warped portion, so that a mechanical load applied to the wire is small. Therefore, the wire passing through the through-hole can be easily connected to the electrode.

In the one aspect, each of the plurality of the wires may electrically connect the first electrode or the second electrode of the first LED chip, to the first electrode or the second electrode of the second LED chip, by a conductive material.

According to this arrangement, the wire can be fixed to the first electrode and the second electrode, and the wire can be electrically connected to the first electrode and the second electrode with high accuracy.

In the one aspect, the light-emitting device may further include a plurality of insulating wires. Moreover, one of the plurality of the insulating wires may pass through the first through-hole and the second through-hole. The plurality of the insulating wires may have higher rigidity than the plurality of the wires.

In the one aspect, the light-emitting device may further include a plurality of insulating wires. The first LED chip may have a third through-hole other than the first through-hole and the second LED chip may have a fourth through-hole other than the second through-hole. One of the plurality of the insulating wires may pass through the third through-hole penetrated through the first LED chip and the fourth through-hole penetrated through the second LED chip. The plurality of the insulating wires may have higher rigidity than the plurality of the wires

According to this arrangement, since the rigidity of the insulating wire is higher than that of the wire, it is possible to reduce a mechanical load applied to the wire when the light-emitting device is deformed (e.g., warped).

A display device according to one aspect of the present disclosure includes the light-emitting device according to the one aspect.

According to this arrangement, the wire penetrates the through-hole and is connected to the electrode. This restricts a movable region of the wire. Therefore, even in a case where the light-emitting device is a display device used in such a manner that a wire substrate is curved, it is possible to provide a display device in which a load applied to a connection point between a wire and an electrode is suppressed.

### Embodiment 1

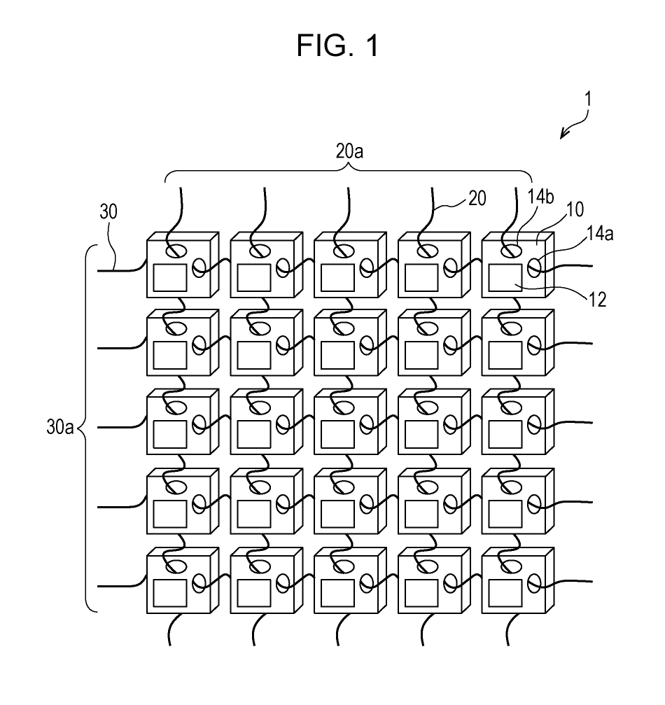

Next, Embodiment 1 is described. FIG. 1 is a conceptual diagram illustrating a configuration of an LED array including a light-emitting device according to the present embodiment.

As illustrated in FIG. 1, a light-emitting device 1 includes a plurality of LED chips 10 disposed in a matrix, a data line group 20a constituted by a plurality of data lines 20, and an address line group 30a constituted by a plurality of address lines 30.

Each of the LED chips 10 has, on a substrate, a light-emitting region 12 and through-holes 14a and 14b.

As illustrated in FIG. 1, the data lines 20 and the address lines 30 penetrate the through-holes 14a and 14b. The data lines 20 penetrate the through-holes 14b of the LED chips 10, and the address lines 30 penetrate the through-holes 14a.

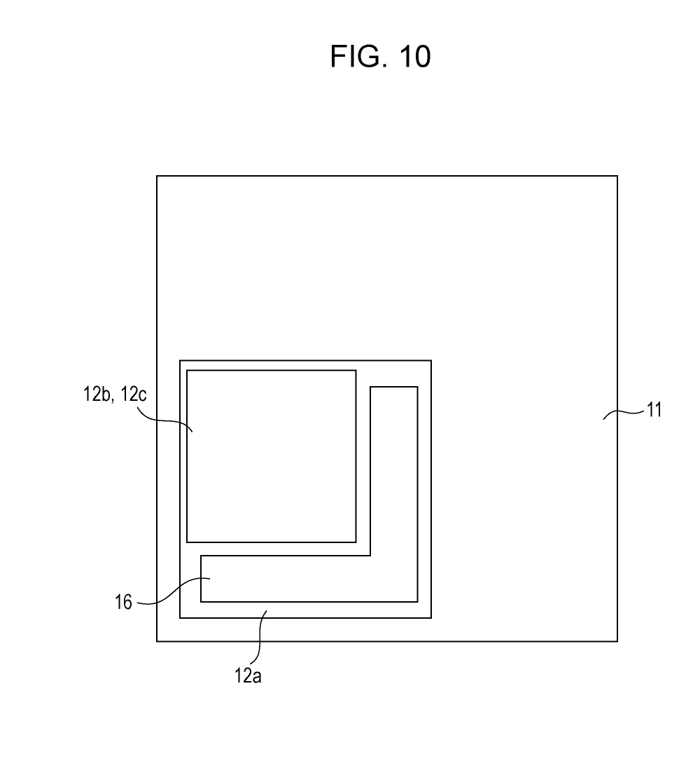

Each of the data lines 20 sequentially penetrates the through-holes 14b in the respective LED chips 10 so as to connect the LED chips 10 in a column direction via an electrode pad (see FIG. 10) that will be described later. Each of the address lines 30 sequentially penetrates the through-holes 14a in the respective LED chips 10 so as to connect the LED chips 10 in a row direction via the electrode pad (see FIG. 10) that will be described later. In this way, as illustrated in FIG. 1, the plurality of LED chips 10 are connected in the row and column directions like a woven fabric by the data lines 20 and the address lines 30. In the through-holes 14a and 14b, at least part of each of side surfaces of the address lines 30 and the data lines 20 is not in contact with inner walls of the through-holes 14a and 14b.

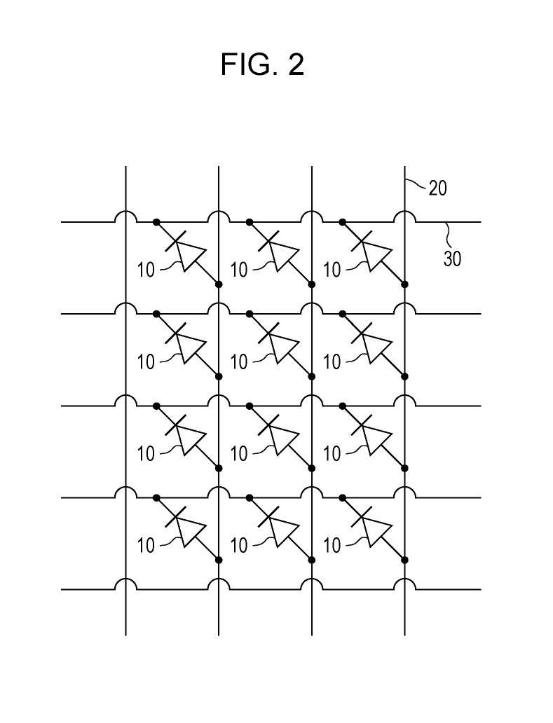

FIG. 2 is an electric circuit diagram of the light-emitting device 1. As illustrated in FIG. 2, the light-emitting device 1 is arranged such that the LED chips 10 are connected between the plurality of data lines 20 and the plurality of address lines 30. In the light-emitting device 1, the LED chips 10 emit light in accordance with a signal supplied from the data lines 20 at a timing at which a signal is applied to the address lines 30.

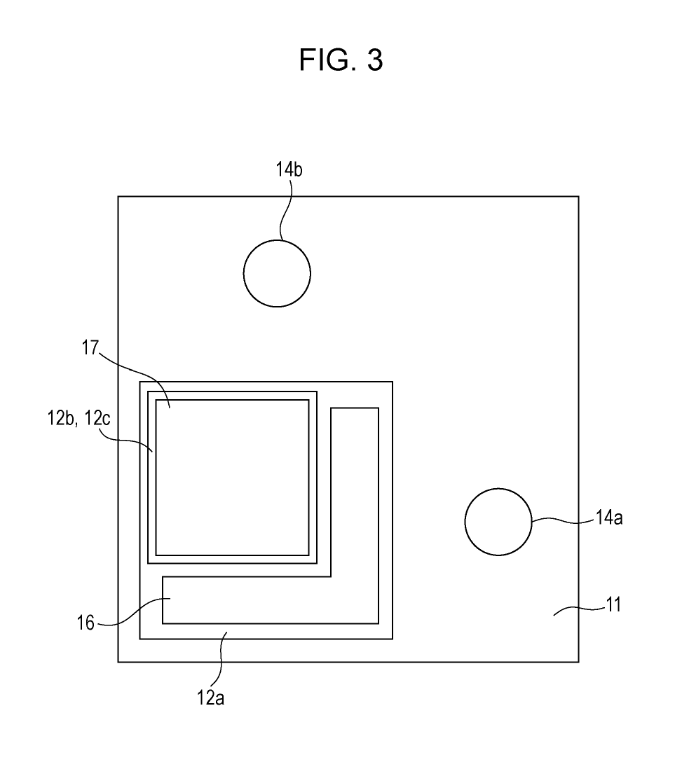

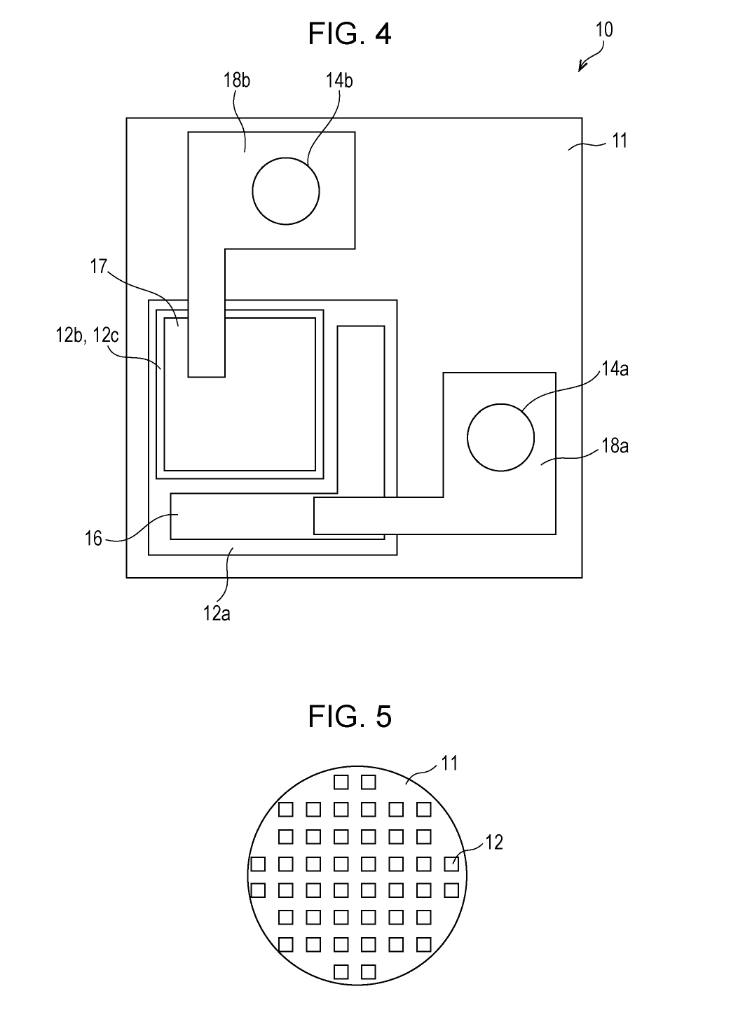

FIGS. 3 and 4 are views schematically illustrating a configuration of an LED chip 10. Note that the LED chip 10 illustrated in FIGS. 3 and 4 corresponds to one of the LED chips 10 illustrated in FIG. 1. Note also that FIG. 4 illustrates a state where an electrode pad is added to the configuration of FIG. 3.

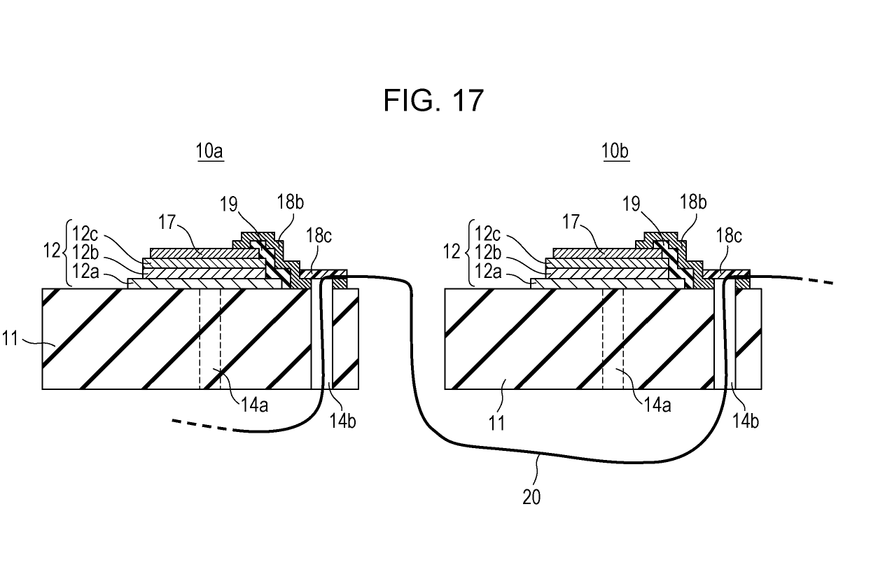

The LED chip 10 has a multi-layer structure in which an n-type semiconductor layer, an active layer, and a p-type semiconductor layer are stacked on a conductive or insulating substrate. For example, the LED chip 10 has a light-emitting region 12 including an active layer 12b (see FIG. 17) on a sapphire substrate 11, which is an insulating substrate. Furthermore, the LED chip 10 has an n-type electrode 16 and a p-type electrode 17 that are formed so as to sandwich the light-emitting region 12.

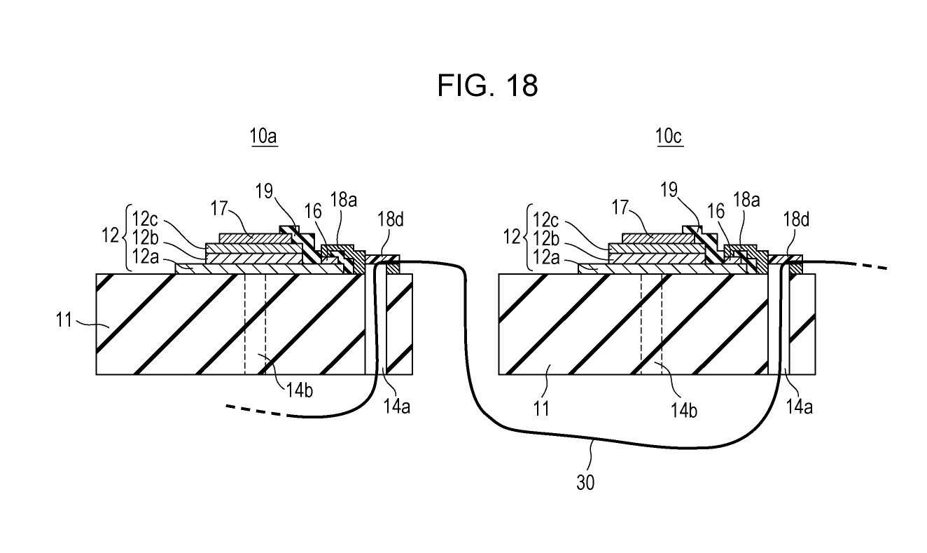

Furthermore, as illustrated in FIG. 4, the n-type electrode 16 is connected to an n-type pad electrode 18a, and the p-type electrode 17 is connected to a p-type pad electrode 18b. More specifically, the n-type pad electrode 18a is electrically connected to the n-type electrode 16, and the n-type pad electrode 18a is insulated from the light-emitting region 12 by an insulating film 19 (see FIG. 18). The p-type pad electrode 18b is electrically connected to the p-type electrode 17, and the p-type pad electrode 18b is insulated from the light-emitting region 12 by the insulating film 19 (see FIG. 17).

The light-emitting region 12 is made up of an n-type semiconductor layer 12a, the active layer (light-emitting layer) 12b, and a p-type semiconductor layer 12c. In the light-emitting region 12, the n-type semiconductor layer 12a, the active layer 12b, and the p-type semiconductor layer 12c are formed on a main surface (not illustrated) of the sapphire substrate 11 from bottom to top in this order. A material of these semiconductor layers can be selected as appropriate in accordance with the wavelength of light emitted by the active layer 12b. For example, these semiconductor layers are made of a GaAs-type or GaN-type compound semiconductor.

When a voltage is applied across the n-type electrode (cathode electrode) 16 and the p-type electrode (anode electrode) 17, an electric current flows through the light-emitting region 12. Thus, the light-emitting region 12 emits light.

Note that the p-type electrode 17 and the p-type pad electrode 18b correspond to a first electrode according to the present disclosure, and the n-type electrode 16 and the n-type pad electrode 18a correspond to a second electrode according to the present disclosure.

The through-holes 14a and 14b are disposed so as to penetrate through at least the sapphire substrate 11 of the LED chip 10. That is, in the LED chip 10, the through-holes 14a and 14b are formed so as to penetrate through the sapphire substrate 11 as positions where through-holes are formed.

The data lines 20 and the address lines 30 are threadlike conductive wires, and are, for example, metal wires made of a metal such as gold (Au), silver (Ag), or Cu (copper). In the present embodiment, the address lines 30 and the data lines 20 are copper electric wires. Each of the data lines 20 and the address lines 30 has, for example, a diameter of 0.1 mm.

Note that it is desirable that the address lines 30 and the data lines 20 have not only conductivity, but also flexibility and stretchability. In this case, the address lines 30 and the data lines 20 can be made of graphite or graphene such as a carbon nanotube. This makes it possible to reduce a load applied to the address lines 30 and the data lines 20 in a case where the light-emitting device 1 is warped. The data lines 20 and the address lines 30 may be coated with a resin.

A plurality of data lines 20 and a plurality of address lines 30 are provided per two adjacent LED chips 10. That is, the address line 30 and the LED chip 10 are alternately provided in the row direction, and the data line 20 and the LED chip 10 are alternately provided in the column direction.

The plurality of address lines 30 connected in one row direction via the LED chips 10 constitute a single scanning line (cathode wire). The plurality of data lines 20 connected in one column direction via the LED chips 10 constitute a single data line (anode wire). The address line group 30a is made up of a plurality of address lines and the data line group 20a is made up of a plurality of data lines.

As illustrated in FIG. 2, in the present embodiment, cathodes of adjacent ones of the plurality of LED chips 10 disposed in the row direction are sequentially connected by the address lines 30. Furthermore, anodes of adjacent ones of the LED chips 10 disposed in the column direction are sequentially connected by the data lines 20.

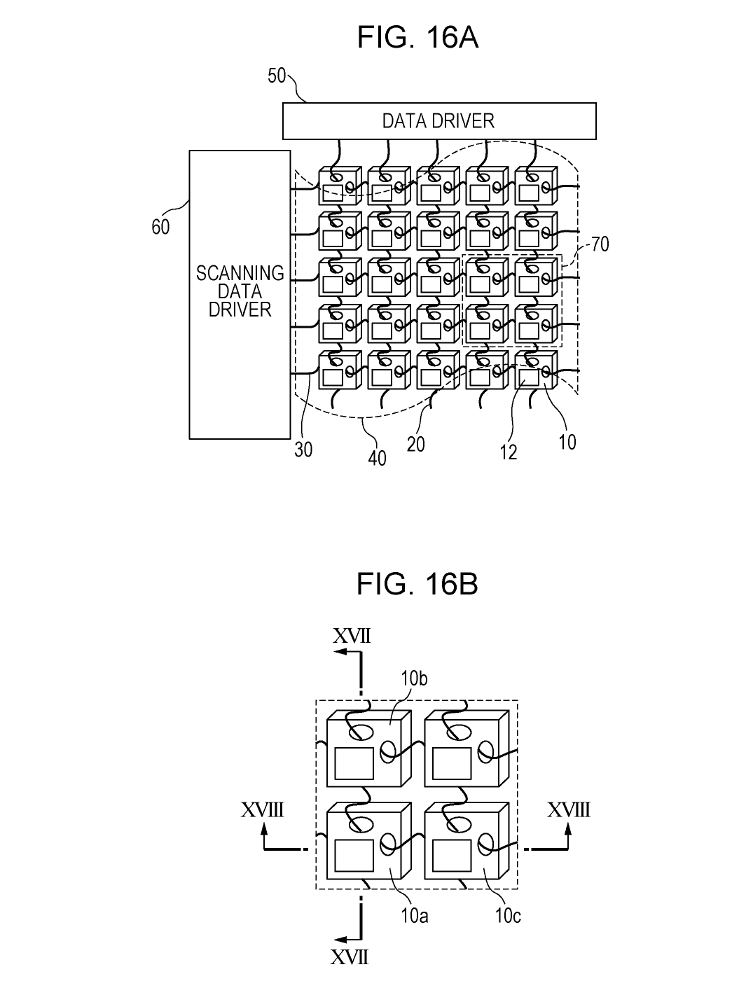

The data line group 20a is connected to a data driver 50 (see FIG. 16A). The address line group 30a is connected to a scanning data driver (source driver) 60.

The data driver 50 and the scanning data driver 60 control a voltage or an electric current applied to the data lines 20 and the address lines 30, respectively. Thus, light-emission operation of the LED chips 10 is controlled.

Note that the data lines 20 correspond to a second wire according to the present disclosure, and the address lines 30 correspond to a first wire according to the present disclosure.

Next, a method for producing the light-emitting device 1 is described.

FIGS. 5 through 7 are views schematically illustrating steps for producing the light-emitting device 1.

As illustrated in FIG. 5, first, a plurality of LED devices are formed on the sapphire substrate 11 that constitutes the light-emitting device 1. Here, the term “LED device” refers to a state before the LED chip is divided into individual chips, A method for forming the LED device (LED chip) 10 will be described in detail later.

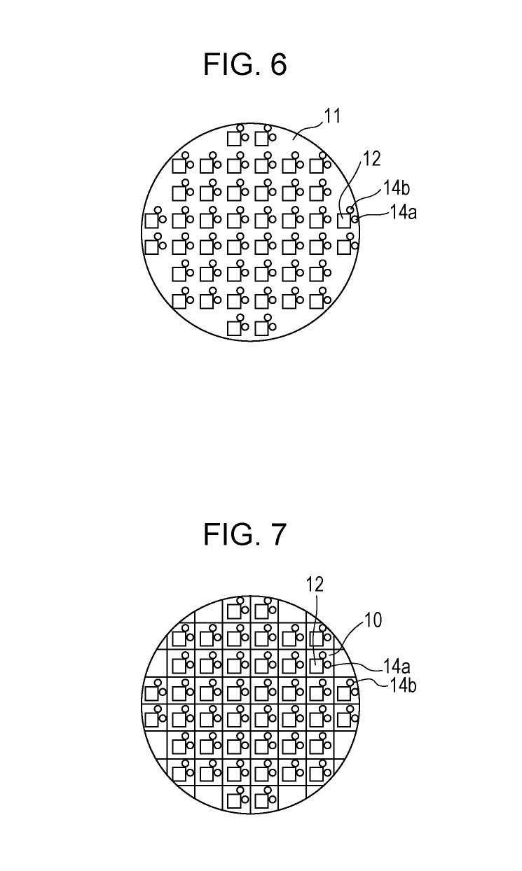

Next, as illustrated in FIG. 6, the through-holes 14a and 14b are formed through the sapphire substrate 11. The plurality of through-holes 14a and 14b that penetrate through both surfaces of the sapphire substrate 11 are formed by using a laser. The plurality of through-holes 14a and 14b are formed around the light-emitting regions 12 of the LED devices (LED chips) 10. The through-holes 14a and 14b may be provided, for example, in the vicinity of the light-emitting regions 12 of the LED devices (LED chips) 10. Details of this will be described later. Alternatively, the through-holes 14a and 14b may be provided within a region in which an electrode (for example, the n-type pad electrode 18a or the p-type pad electrode 18b) of the LED device (LED chip) 10 is formed.

Then, as illustrated in FIG. 7, the sapphire substrate 11 on which the LED devices are formed is divided into the LED chips 10 by dicing.

The following describes a method for producing the LED chip (LED device) 10.

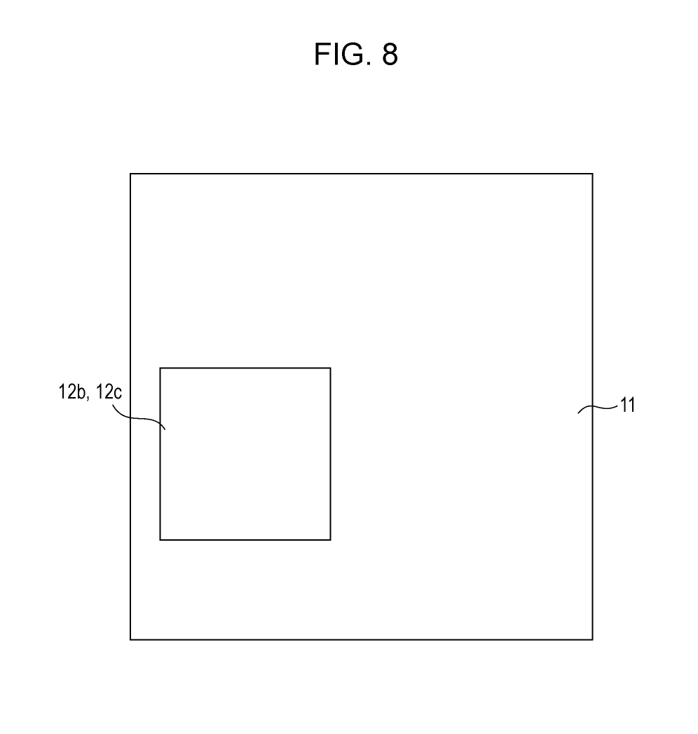

FIGS. 8 through 14 are top views each illustrating steps for producing the LED chip 10.

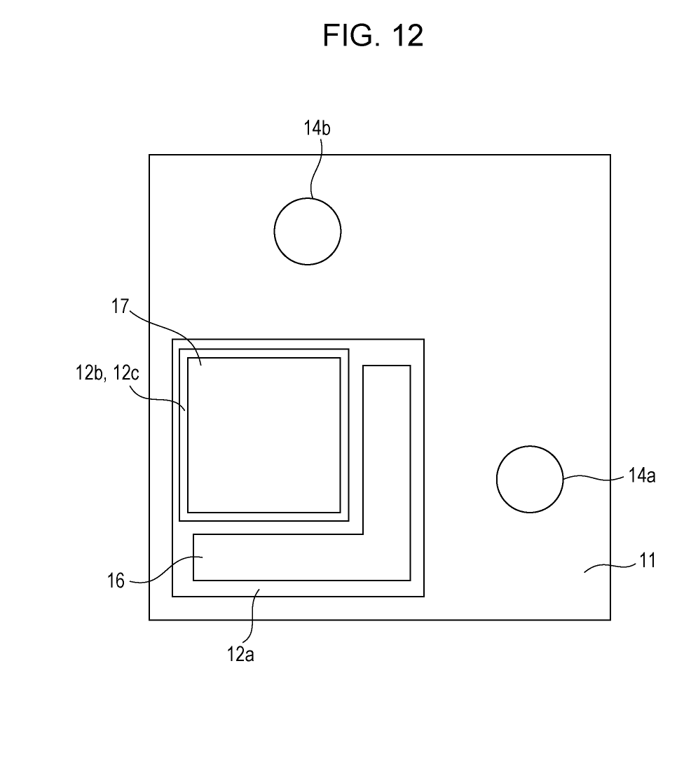

First, a substrate (multi-layer structure) in which a semiconductor layer is stacked on the sapphire substrate 11 is prepared. The semiconductor layer is a layer that constitutes the light-emitting region 12. In the light-emitting region 12, the n-type semiconductor layer 12a, the active layer 12b, and the p-type semi conductor layer 12c are stacked in this order. Then, the multi-layer structure is etched by using a resist, SiO₂, or the like as a mask so that the active layers 12b and 12c remain as illustrated in FIG. 8 and so that the n-type semiconductor layer 12a is exposed as illustrated in FIG. 12. Thus, the n-type semiconductor layer 12a is exposed in the LED chip 10.

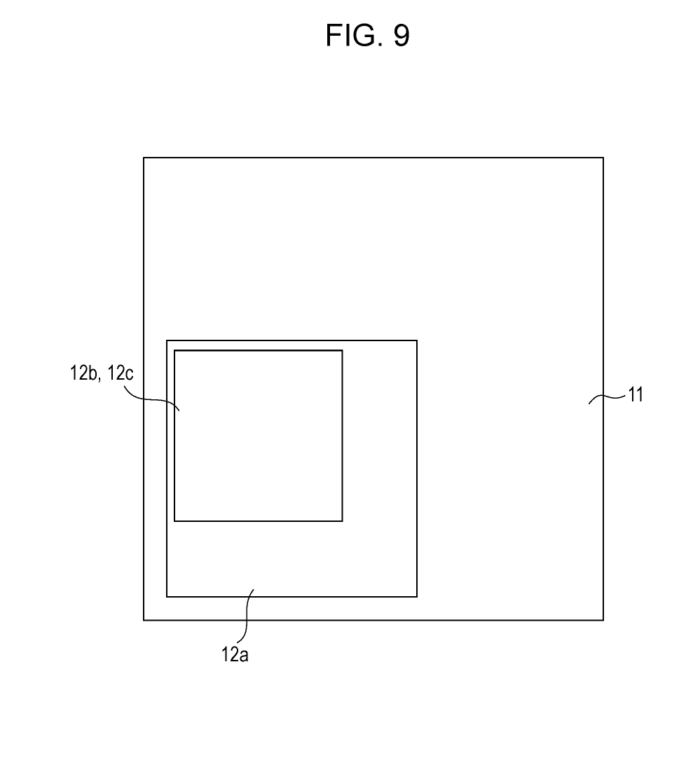

Next, as illustrated in FIG. 9, a region of the semiconductor layer other than the n-type semiconductor layer 12a is etched so that the sapphire substrate 11 is exposed while leaving the n-type semiconductor layer 12a.

Furthermore, an insulating film (not illustrated) for insulation of a p-n junction is formed so that the p-type semiconductor layer 12c (or the p-type electrode 17) and the n-type semiconductor layer 12a (or the n-type electrode 16) are not short-circuited.

Subsequently, as illustrated in FIG. 10, the n-type electrode 16 is formed on the n-type semiconductor layer 12a. The n-type electrode is, for example, formed in an L-shape on the n-type semiconductor layer 12a so as to be parallel with two sides of the n-type semiconductor layer 12a.

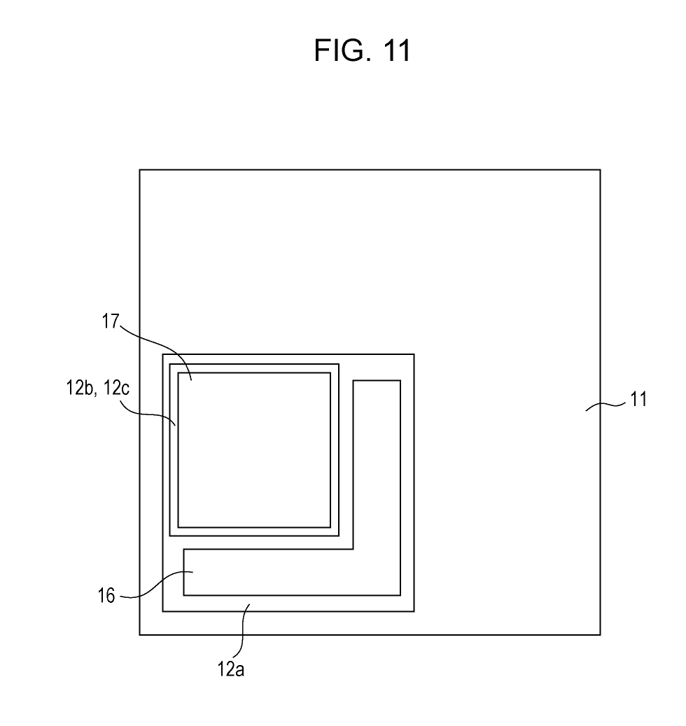

Next, as illustrated in FIG. 11, the p-type electrode 17 is formed on the p-type semiconductor layer 12c. The p-type electrode 17 is formed on the p-type semiconductor layer 12c so as to have a substantially identical shape to the p-type semiconductor layer 12c.

Furthermore, as illustrated in FIG. 12, the through-holes 14a and 14b are formed in the LED chip 10. The through-holes 14a and 14b are formed by laser processing as described above.

Furthermore, the n-type pad electrode 18a and the p-type pad electrode 18b are formed on the n-type electrode 16 and the p-type electrode 17, respectively. The n-type pad electrode 18a and the p-type pad electrode 18b are, for example, made of copper, and are patterned to a predetermined shape, Thus, the n-type electrode 16 and the n-type pad electrode 18a are electrically connected to each other, and the p-type electrode 17 and the p-type pad electrode 18b are electrically connected to each other.

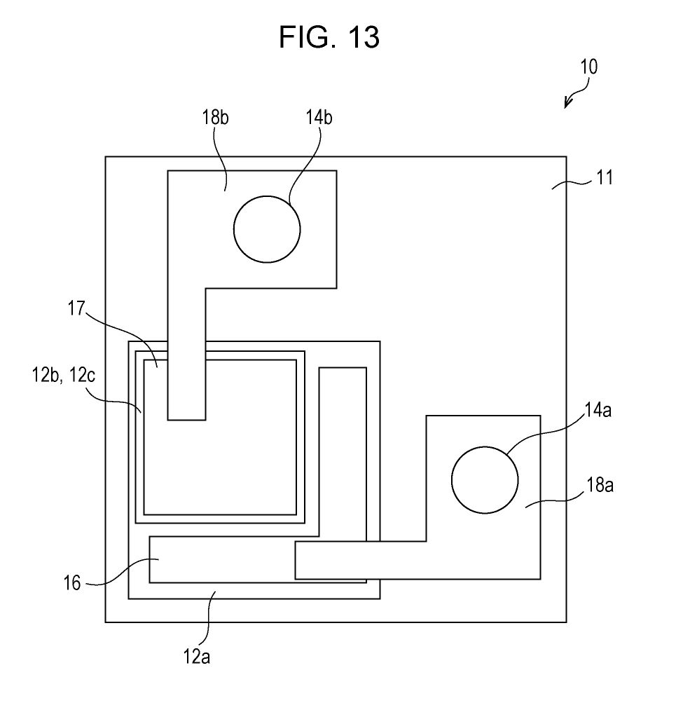

Through these steps, the LED chip 10 illustrated in FIG. 13 is completed. According to this configuration, wires (the address lines 30 and the data lines 20) penetrate the through-holes 14a and 14b and are then connected to electrodes (the n-type pad electrode 18a and the p-type pad electrode 18b). This restricts a movable region of the wires, thereby suppressing a mechanical load applied to connection points between the wires and the electrodes.

Note that in a case where the above-mentioned elements of the LED chip 10 are formed, a mask pattern used for patterning is not limited to the pattern described in the above embodiment and may be another pattern. Furthermore, the steps for producing the light-emitting device 1 are not limited to the above-mentioned steps. The order of the steps may be changed or another step may be added. Furthermore, the through-holes 14a and 14b may be formed after formation of the n-type pad electrode 18a and the p-type pad electrode 18b of the LED chip 10 or may be formed before formation of the n-type pad electrode 18a and the p-type pad electrode 18b of the LED chip 10. According to the arrangement, the through-holes 14a and 14b, the n-type pad electrode 18a, and the p-type pad electrode 18b can be easily formed.

The through-holes 14a and 14b may be formed so as to penetrate through not just the sapphire substrate 11 but a multi-layer body having the sapphire substrate 11, the p-type semiconductor layer 12c, and the n-type semiconductor layer 12a. Alternatively, the through-holes 14a and 14b may be formed so as to penetrate through at least one of the n-type semiconductor layer 12a and the p-type semiconductor layer 12c of the multi-layer body.

According to this arrangement, the wires made up of the data lines 20 and the address lines 30 penetrate the through-holes 14a and 14b and are then connected to an electrode (the n-type electrode 16 or the p-type electrode 17). This restricts a movable region of the wires, thereby suppressing a mechanical load applied to connection points between the wires and the electrodes.

The number of through-holes 14a and 14b provided in the LED chip 10 is not limited to two as in the light-emitting device 1 described above. A larger number of through-holes may be provided. In this case, the through-holes need not have an identical diameter. A plurality of through-holes that have different diameters may be formed. One example is described below.

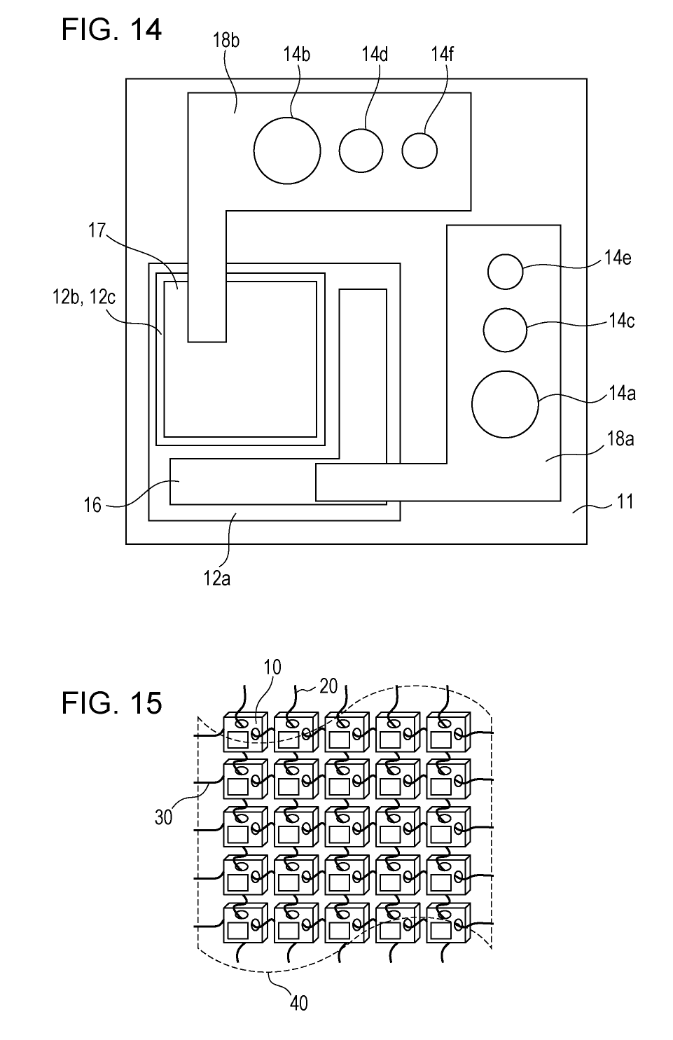

FIG. 14 is a top view illustrating a configuration of an LED chip 10 that has a plurality of through-holes having different diameters.

As illustrated in FIG. 14, the LED chip 10 may include through-holes 14c, 14d, 14e, and 14f in addition to the through-holes 14a and 14b of the LED chip 10 of the light-emitting device 1 described above. The through-holes 14a, 14c, and 14e are formed inside the n-type pad electrode 18a. The through-holes 14b, 14d, and 14f are formed inside the p-type pad electrode 18b.

Of the through-holes 14a, 14c, and 14e formed in the n-type pad electrode 18a, the through-hole 14a has the largest diameter, the through-hole 14c has the second largest diameter, and the through-hole 14e has the smallest diameter. Similarly, of the through-holes 14b, 14d, and 14f formed in the p-type pad electrode 18b, the through-hole 14b has the largest diameter, the through-hole 14d has the second largest diameter, and the through-hole 14f has the smallest diameter.

By thus forming a plurality of through-holes having different diameters, an appropriate one of the through-holes having different diameters can be used in accordance with the diameter of a wire. This makes it possible to easily and efficiently reduce a mechanical load applied to the wire.

The address line 30 and the data line 20 are run through the through-holes 14a and 14b of the completed LED chip 10, The data line 20 sequentially penetrates the through-holes 14b of the plurality of LED chips 10 so as to connect the plurality of LED chips 10 in the column direction. The address line 30 sequentially penetrates the through-holes 14a of the plurality of LED chips 10 so as to connect the plurality of LED chip 10 in the row direction. In this way, in the light-emitting device 1, the plurality of LED chips 10 are connected in the row and column directions by the data lines 20 and the address lines 30 like a woven fabric. A method for connecting the plurality of LED chips 10 will be described later in detail.

Furthermore, as illustrated in FIG. 15, the light-emitting device 1 in which the plurality of LED chips 10 are connected in the row and column directions like a woven fabric is fixed onto a film 40 made of a material such as a flexible resin material. This makes it possible to provide the light-emitting device 1, for example, on a flexible substrate or the like of a panel.

Furthermore, as illustrated in FIG. 16A, in the light-emitting device 1 fixed onto the film 40, the data lines 20 and the address lines 30 are connected to the data driver 50 and the scanning data driver 60, respectively. This allows the data driver 50 and the scanning data driver 60 to control a light emission operation of the LED chips 10.

The following describes an example of a method for connecting the plurality of LED chips 10 by using the data lines 20 and the address lines 30,

FIG. 17 is a cross-sectional view taken along the line XVII-XVII of the light-emitting device 1 illustrated in FIG. 16B. FIG. 18 is a cross-sectional view taken along the line XVIII-XVIII of the light-emitting device 1 illustrated in FIG. 16B. Note that LED chips 10a through 10c in FIGS. 17 and 18 correspond to LED chips 10a through 10c illustrated in FIG. 16B.

As illustrated in FIG. 17, the data line 20, which is a wire, is connected to the p-type pad electrode 18b formed on the front surface of one LED chip 10a by a conductive material (for example, a conductive resin) 18c and penetrate the through-hole 14b formed through the LED chip 10a from the front surface to the rear surface of the LED chip 10a. Furthermore, the data line 20 penetrates the through-hole 14b formed through another LED chip 10b from the rear surface to the front surface of the LED chip 10b and are connected to the p-type pad electrode 18b formed on the front surface of this LED chip 10b by a conductive resin 18c.

Thus, the data line 20 that penetrates the through-hole 14b of the LED chip 10a is electrically connected to the adjacent LED chip 10b, and a movable region of the data line 20 is restricted. This makes it possible to suppress a mechanical load applied to connection points between the data line 20 and the p-type pad electrodes 18b.

Furthermore, as illustrated in FIG. 18, the address line 30, which is a wire, is connected to the n-type pad electrode 18a formed on the front surface of one LED chip 10a by a conductive material (for example, a conductive resin) 18d and penetrates the through-hole 14a formed through the LED chip 10a from the front surface to the rear surface of the LED chip 10a, Furthermore, the address line 30 penetrates the through-hole 14a formed through another LED chip 10c from the rear surface to the front surface of the LED chip 10c and is connected to the n-type pad electrode 18a formed on the front surface of the LED chip 10c by a conductive resin 18c.

Thus, the address line 30 that penetrates the through-hole 14a of the LED chip 10a is electrically connected to the adjacent LED chip 10c, and a movable region of the address line 30 is restricted. This makes it possible to suppress a mechanical load applied to connection points between the address line 30 and the n-type pad electrodes 18a.

Through these processes, the light-emitting device 1 according to the present embodiment is completed.

According to the above arrangement, the wires (the data lines 20 and the address lines 30) penetrate the through-holes and are then connected to the electrodes. This restricts a movable region of the wires, thereby suppressing a mechanical load applied to connection points between the wires and the electrodes.

Note that in a case where the above-mentioned elements of the LED chip 10 are formed, a mask pattern used for patterning is not limited to the pattern described in the above embodiment and may be another pattern. Furthermore, the steps for producing the light-emitting device 1 are not limited to the above-mentioned steps. The order of the steps may be changed or another step may be added. Furthermore, the through-holes 14a and 14b may be formed after formation of the n-type pad electrode 18a and the p-type pad electrode 18b of the LED chip 10 or may be formed before formation of the n-type pad electrode 18a and the p-type pad electrode 18b of the LED chip 10. According to the arrangement, the through-holes, the n-type pad electrode, and the p-type pad electrode can be easily formed.

The through-holes 14a and 14b may be formed so as to penetrate through not just the substrate but a multi-layer body having the sapphire substrate 11, the p-type semiconductor layer 12c, and the n-type semiconductor layer 12a. Alternatively, the through-holes 14a and 14b may be formed so as to penetrate through at least one of the n-type semiconductor layer 12a and the p-type semiconductor layer 12c of the multi-layer body. According to this arrangement, the wires made up of the data lines 20 and the address lines 30 penetrate the through-holes 14a and 14b and are then connected to the electrode (the n-type electrode 16 or the p-type electrode 17). This restricts a movable region of the wires. This makes it possible to suppress a mechanical load applied connection points between the wires and the electrodes.

The substrate is not limited to the sapphire substrate 11. The substrate may be a conductive substrate or may be made up of an n-type semiconductor layer. The conductive substrate may be, for example, an oxide semiconductor. The n-type semiconductor layer may be, for example, GaN. This makes it possible to easily form the light-emitting device 1. In this case, the through-holes 14a and 14b need just be formed so as to penetrate through both surfaces of the multi-layer structure, that is, from the front surface to the rear surface of the multi-layer structure. That is, in a case where the multi-layer structure at positions where the through-holes 14a and 14b are formed is made up of an n-type semiconductor layer only, the through-holes 14a and 14b need just be formed so as to penetrate through both surfaces of the n-type semiconductor layer of the multi-layer structure.

According to the light-emitting device 1 according to the present embodiment, the wires, that is, the data line 20 and the address line 30 that are connected to the p-type pad electrode 18b and the n-type pad electrode 18a of one LED chip 10a penetrate the through-holes 14b and 14a formed through this LED chip 10a and are then connected to the electrodes of other LED chips 10b and 10c, This restricts a movable region of the wires, thereby suppressing a mechanical bad applied to connection points between the wires and the electrodes.

### Modification of Embodiment 1

Next, a modification of Embodiment 1 is described. A light-emitting device according to the present modification employs a semiconductor substrate as a substrate that constitutes an LED chip, and through-holes are provided through this semiconductor substrate.

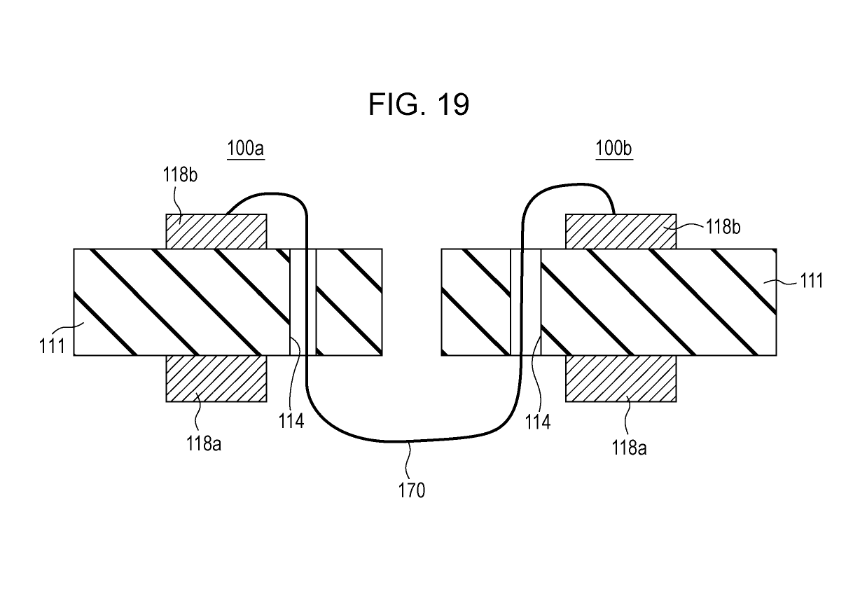

FIG. 19 is a cross-sectional view illustrating configurations of LED chips 100a and 100b. In FIG. 19, a data line 20 and an address line 30 are collectively illustrated as a wire 170.

As illustrated in FIG. 19, each of the LED chips 100a and 100b includes, on a substrate 111, a p-type pad electrode 118b, which is a first electrode, and an n-type pad electrode 118a, which is a second electrode. A semiconductor substrate is used as the substrate 111. The substrate 111 is, for example, a substrate made up of an n-type semiconductor layer. The substrate 111 may have a multi-layer structure made up of an n-type semiconductor layer, an active layer (light-emitting layer), and a p-type semiconductor layer as described in Embodiment 1 described above.

An insulating film (not illustrated) is formed between the n-type pad electrode 118a and the wire 170 that penetrates the through-hole 114 and between the p-type pad electrode 118b and the wire 170 that penetrates the through-hole 114. For example, the insulating film is formed on an inner surface of the through-hole 114. In a case where the insulating film is formed on the inner surface of the through-hole 114, insulation can be secured between the n-type pad electrode 118a and the wire and between the p-type pad electrode 118b and the wire. Note that the insulating film may be formed not only on the through-hole 114 but also on the wire. For example, the wire may be coated with a resin.

The wire 170 is connected to the p-type pad electrode 118b formed on the front surface of the LED chip 100a and penetrates the through-hole 114 formed through the LED chip 100a from the front surface to the rear surface of the LED chip 100a. Furthermore, the wire 170 penetrates the through-hole 114 formed through the LED chip 100b from the rear surface to the front surface of the LED chip 100b and is connected to the p-type pad electrode 118b formed on the front surface of another LED chip 100b.

This produces an arrangement in which the wire 170 is electrically connected between the adjacent LED chips 100a and 100b, and a movable region of the wire 170 is restricted. It is therefore possible to suppress a mechanical load applied to connection points between the wire 170 and the p-type pad electrodes 118b.

In FIG. 19, the light-emitting device in which the wire 170 connects the p-type pad electrodes 118b has been described. However, the light-emitting device is not limited to this example. It is only necessary that the wire 170 passes through the through-hole 114 when connected between the adjacent LED chips 100a and 100b. The wire 170 may connect the n-type pad electrodes 118a. Alternatively, the wire 170 may connect the n-type pad electrode 118a of the LED chip 100a and the p-type pad electrode 118b of the adjacent LED chip 100b.

Note that the wire 170 that penetrates the through-hole 114 is not limited to the data line 20 and the address line 30. The wire 170 may be an insulating wire that has no conductivity. In this case, the insulating wire is not connected to the n-type pad electrode 118a and the p-type pad electrode 118b. This insulating wire is used to connect other LED chips by sequentially penetrating the through-holes 114 of the LED chips.

According to the light-emitting device according to the present modification, also in a case where the substrate that constitutes the LED chips 100a and 100b is a semiconductor substrate, the wire sequentially penetrates the through-holes 114 of the LED chips 100a and 100b so as to connect the LED chips. It is therefore possible to suppress a mechanical load applied to a connection point between a wire and an electrode.

### Embodiment 2

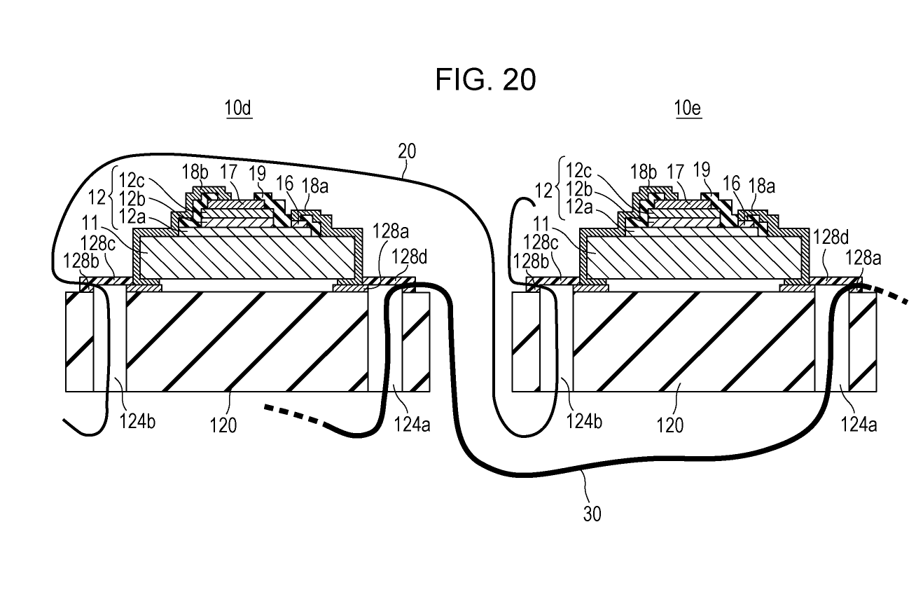

Next, Embodiment 2 is described. FIG. 20 is a cross-sectional view illustrating a configuration of a light-emitting device according to the present embodiment,

The light-emitting device according to the present embodiment is different from the light-emitting device according to Embodiment 1 in that LED chips are mounted on a substrate provided with a plurality of through-holes. The substrate having the through-holes may be different from a substrate on which a light-emitting region of an LED is formed. That is, it is unnecessary that the substrate having the through-holes be a conductive substrate.

As illustrated in FIG. 20, an LED chip 10d includes a sapphire substrate 11, an n-type pad electrode 18a, which is a cathode electrode, and a p-type pad electrode 18b, which is an anode electrode. In a light-emitting region 12, an n-type semiconductor layer 12a, an active layer 12b, and a p-type semiconductor layer 12c are stacked on the sapphire substrate 11. The n-type pad electrode 18a and the p-type pad electrode 18b run along the side surfaces of the sapphire substrate 11 and extend to the rear surface of the sapphire substrate 11.

Meanwhile, the sapphire substrate 11 is mounted on another substrate 120 through which through-holes 124a and 124b are formed. An n-type connection electrode 128a is formed on a surface of the substrate 120 so as to be located around the opening of the through-hole 124a. Furthermore, a p-type connection electrode 128b is formed on the surface of the substrate 120 so as to be located around the opening of the through-hole 124b. The n-type connection electrode 128a and the p-type connection electrode 128b are electrically connected to the n-type pad electrode 18a and the p-type pad electrode 18b, respectively. Note that the substrate 120 may be, for example, a printed substrate or a glass substrate.

A data line 20 is connected to the p-type connection electrode 128b of the LED chip 10d. The data line 20 penetrates the through-hole 124b of the LED chip 10d, penetrates a through-hole 124b of an adjacent LED chip 10e, and is connected to a p-type connection electrode 128b of the LED chip 10e.

Furthermore, an address line 30 is connected to the n-type connection electrode 128a of the LED chip 10d. The address line 30 penetrates the through-hole 124a of the LED chip 10d, penetrates a through-hole 124a of the adjacent LED chip 10e, and is connected by an n-type connection electrode 128a of the LED chip 10e.

Connection between the data line 20 and the p-type connection electrode 128b of the LED chip 10d and connection between the data line 20 and the p-type connection electrode 128b of the LED chip 10e may be achieved by a conductive resin 128c formed on the top surface of the p-type connection electrode 128b, as in Embodiment 1 described above.

Similarly, connection between the address line 30 and the n-type connection electrode 128a of the LED chip 10d and connection between the address line 30 and the n-type connection electrode 128a of the LED chip 10e may be achieved by a conductive resin 128d formed on the top surface of the n-type connection electrode 128a.

Note that, in the present embodiment, the arrangement in which the electrodes on the sapphire substrate 11 and the electrodes on the substrate 120 are connected by surface mounting. However, such an arrangement is also possible in which the electrodes on the sapphire substrate 11 and the electrodes on the substrate 120 are connected by wire bonding.

According to the light-emitting device according to the present embodiment, a substrate having a plurality of through-holes and a plurality of LED chips 10 can be separately prepared. It is therefore possible to easily produce a light-emitting device.

### Embodiment 3

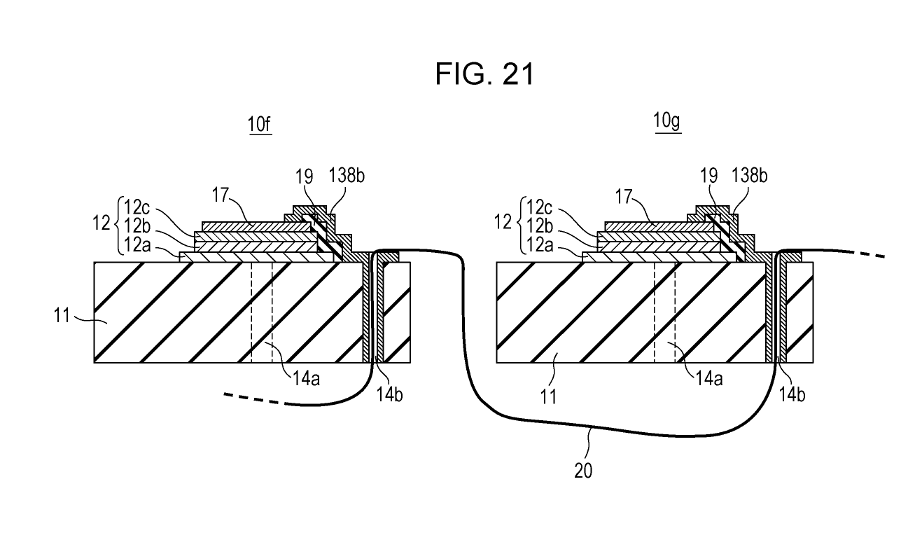

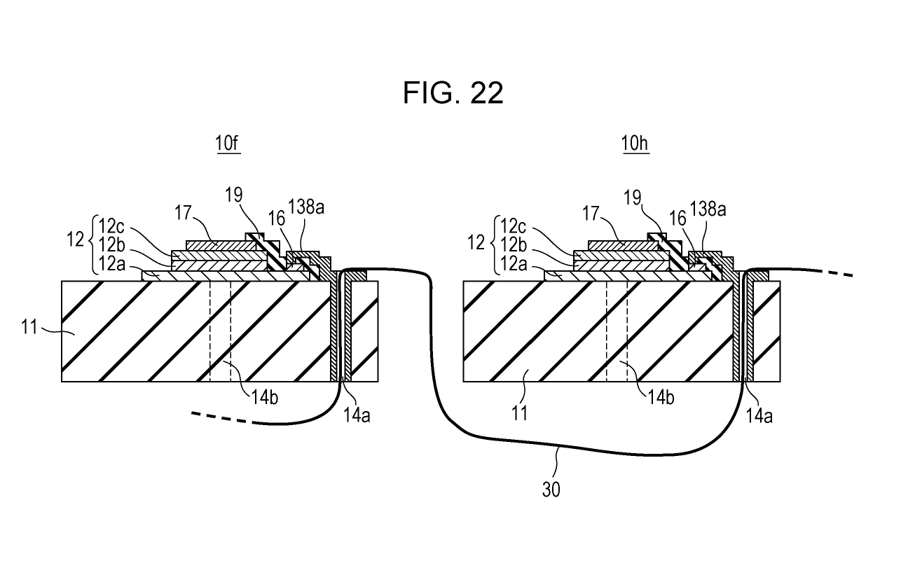

Next, Embodiment 3 is described. FIGS. 21 and 22 are cross-sectional views each illustrating a configuration of a light-emitting device according to the present embodiment.

The light-emitting device according to the present embodiment is different from the light-emitting devices described in Embodiments 1 and 2 in that insides of through-holes are covered with a conductive material.

As illustrated in FIG. 21, inner surfaces of through-holes 14b provided through sapphire substrates 11 of LED chips 10f and 10g are covered with a p-type pad electrode 138b. In a case where the inner surfaces of the through-holes 14b are covered with the p-type pad electrode 138b, electrical connection with a data line 20 can be easily achieved.

Similarly, as illustrated in FIG. 22, inner surfaces of through-holes 14a provided through the sapphire substrates 11 of the LED chips 10f and 10h are covered with an n-type pad electrode 138a. In a case where the inner surfaces of the through-holes 14a are covered with the n-type pad electrode 138a, electrical connection with a wire 30 can be easily achieved.

Note that the wires that penetrate the through-holes 14a and 14b are not limited to the data line 20 and the address line 30. These wires may be insulating wires having no conductivity. In this case, the insulating wires are not connected to the n-type pad electrode 138a and the p-type pad electrode 138b. Instead, the insulating wires may mechanically connect the LED chips by sequentially penetrating through-holes of other LED chips. The case where the insulating wires having no conductivity penetrate the through-holes will be described later in detail.

According to the light-emitting device according to the present embodiment, insides of through-holes are covered with a conductive material. It is therefore possible to easily achieve electrical connection between the n-type pad electrode 138a or the p-type pad electrode 138b and the wire that penetrates the through-holes.

### Embodiment 4

Next, Embodiment 4 is described.

The light-emitting device described above may have not only a wire having conductivity but also an insulating wire having no conductivity. A light-emitting device having an insulating wire is described below.

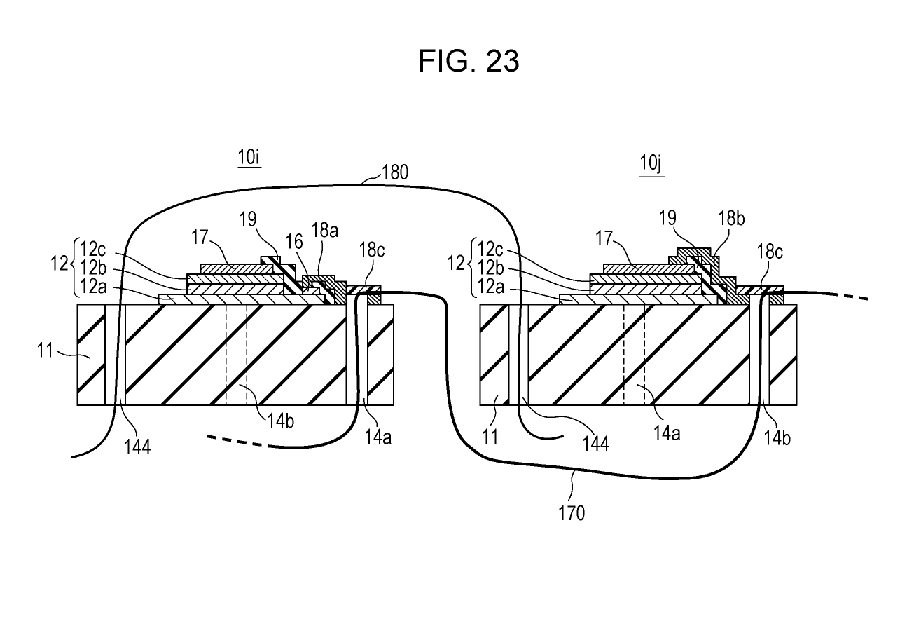

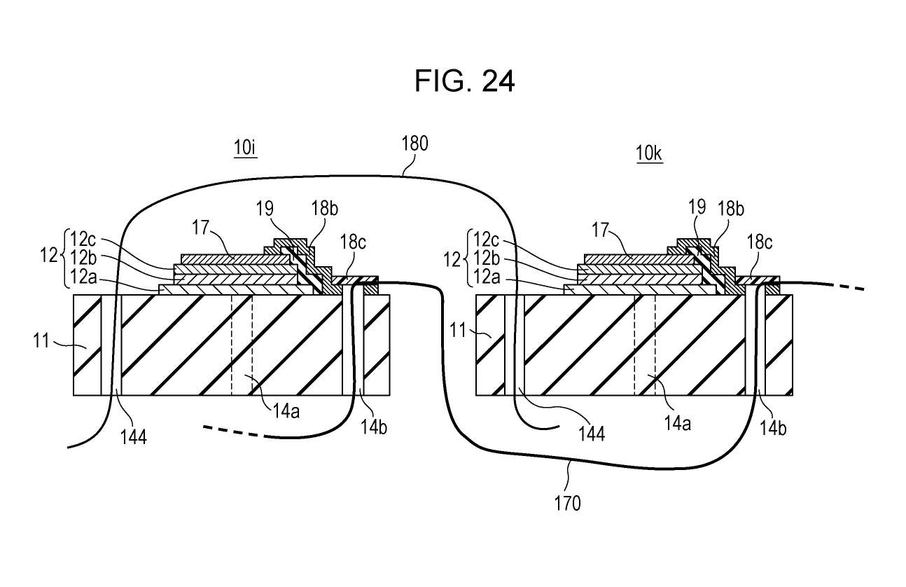

FIGS. 23 and 24 are cross-sectional views each illustrating a configuration of a light-emitting device according to the present embodiment.

As illustrated in FIG. 23, the light-emitting device according to the present embodiment includes an n-type pad electrode 18a, which is a cathode electrode, on a surface of a substrate 11 of an LED chip 10i and includes a p-type pad electrode 18b, which is an anode electrode, on a surface of a substrate 11 of an LED chip 10j adjacent to the LED chip 10i. Through-holes 14a, 14b, and 144 are formed through each of the LED chips 10i and 10j. A wire 170 having conductivity (for example, a data line 20 or an address line 30) is connected to the n-type pad electrode 18a of the LED chip 10i by a conductive resin 18c.

The wire 170 penetrates the through-hole 14a formed through the LED chip 10i, penetrates the through-hole 14b of the adjacent LED chip 10j, and is connected to the p-type pad electrode 18b by the conductive resin 18c. That is, the n-type pad electrode 18a of the LED chip 10i and the p-type pad electrode 18b of the LED chip 10j are connected via the through-holes 14a and 14b.

Furthermore, an insulating wire 180 having no conductivity penetrates the through-hole 144 formed through the LED chip 10i. The insulating wire 180 is, for example, made up of a resin material. The insulating wire 180 may be a metallic wire coated with an insulating material such as a resin material. The insulating wire 180 also penetrates the through-hole 144 of the adjacent LED chip 10j. The insulating wire 180 further sequentially penetrates through-holes of adjacent LED chips (not illustrated). Thus, the LED chips constitute a fabric-like light-emitting device. In a case where the insulating wire 180 is used, the LED chips are fixed to each other by the insulating wire 180. It is therefore possible to obtain a fabric-like light-emitting device having high mechanical strength.

The insulating wire 180 may be made of a material having higher rigidity than the wire 170. In a case where the rigidity of the insulating wire 180 is higher than that of the wire 170, it is possible to further reduce a mechanical bad applied to the wire 170 when the light-emitting device is deformed (e.g., warped).

Note that the wire 170 may connect the p-type pad electrodes 18b or the n-type pad electrodes 18a of the adjacent LED chips 10i and 10j, instead of connecting the n-type pad electrode 18a of the LED chip 10i and the p-type pad electrode 18b of the LED chip 10j.

For example, as illustrated in FIG. 24, the wire 170 is connected to the p-type pad electrode 18b of the LED chip 10i. The wire 170 penetrates the through-hole 14b formed through the LED chip 10i and is connected to a p-type pad electrode 18b of an adjacent LED chip 10k. Thus, the wire 170 connects the p-type pad electrodes 18b of the adjacent LED chips 10i and 10k.

Note that the wire 170 may be connected to the n-type pad electrode 18a of the LED chip 10i, penetrate the through-hole 14a formed through the LED chip 10i, and be connected to the n-type pad electrode 18a of an adjacent another LED chip 10k. Thus, the wire 170 connects the n-type pad electrodes 18a of the adjacent LED chips 10i and 10k.

In a case where the insulating wire 180 is used, a plurality of LED chips are fixed to each other. It is therefore possible to obtain a fabric-like light-emitting device having high mechanical strength.

### Modification of Embodiment 4

Next, a modification of Embodiment 4 is described.

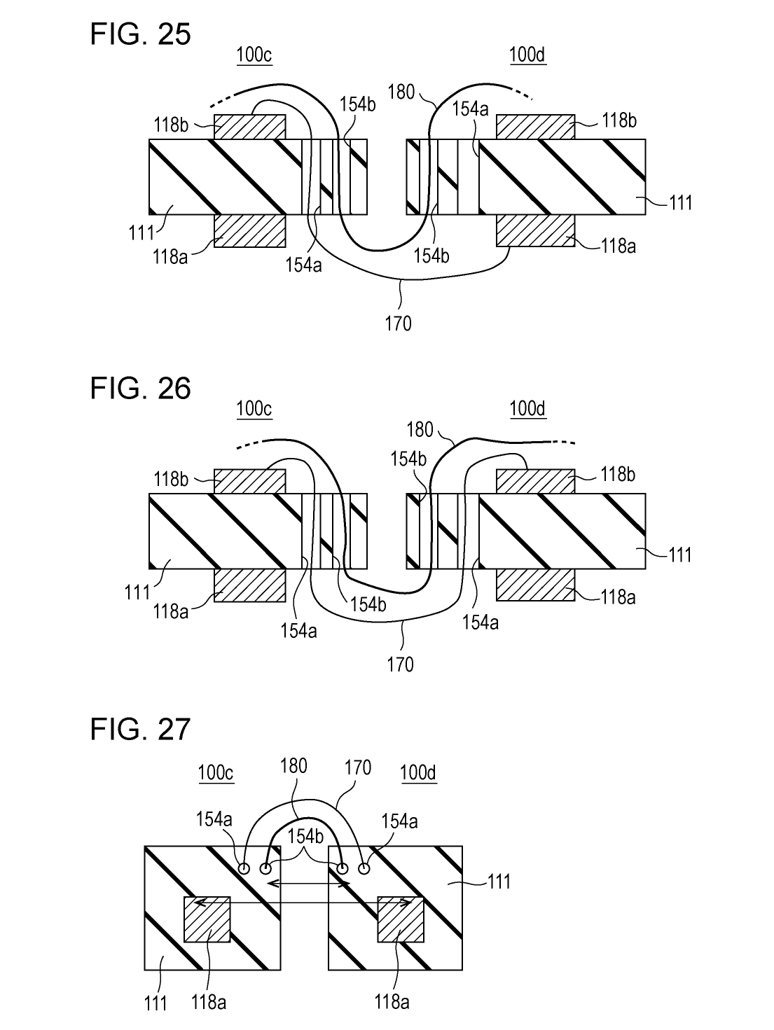

FIGS. 25 and 26 are cross-sectional views each illustrating a configuration of a light-emitting device according to the present modification.

The light-emitting device according to the present embodiment is different from the light-emitting device according to Embodiment 4 in that a substrate that constitute LED chips is a semiconductor substrate, and through-holes are provided through this semiconductor substrate. The semiconductor substrate is a substrate (multi-layer structure) made up of semiconductor layers that are stacked on each other. The semiconductor layers are layers that constitute a light-emitting region 12, as in the above embodiments. In the light-emitting region 12, an n-type semiconductor layer 12a, an active layer 12b, and a p-type semiconductor layer 12c are stacked in this order.

As illustrated in FIG. 25, in the light-emitting device according to the present modification, LED chips 100c and 100d each include an n-type pad electrode 118a, which is a cathode electrode, on the rear surface of the substrate (multi-layer structure) 111 and includes a p-type pad electrode 118b, which is an anode electrode, on the front surface of the substrate (multi-layer structure) 111.

Furthermore, through-holes 154a and 154b are formed through each of the LED chips 100c and 100d. Furthermore, a wire 170 having conductivity (for example, a data line 20 or an address line 30) is connected to the p-type pad electrode 118b of the LED chip 100c.

The wire 170 penetrates the through-hole 154a formed through the LED chip 100c and is connected to the n-type pad electrode 118a of the adjacent LED chip 100d. That is, the p-type pad electrode 118b of the LED chip 100c and the n-type pad electrode 118a of the adjacent LED chip 100d are connected via the through-hole 154a.

Furthermore, an insulating wire 180 having no conductivity penetrates the through-hole 154b formed through the LED chip 100c. The insulating wire 180 is, for example, made of a resin material The insulating wire 180 may be a metallic wire coated with an insulating material such as a resin material The insulating wire 180 penetrates the through-hole 154b of the adjacent LED chip 100d. The insulating wire 180 further sequentially penetrate through-holes 154b of a plurality of adjacent LED chips (not illustrated). Thus, the LED chips constitute a fabric-like light-emitting device. In a case where the insulating wire 180 is used, the plurality of LED chips are fixed to each other by the insulating wire 180. It is therefore possible to obtain a fabric-like light-emitting device having high mechanical strength.

The insulating wire 180 may be made of a material having higher rigidity than the wire 170. In a case where the rigidity of the insulating wire 180 is higher than that of the wire 170, it is possible to further reduce a mechanical load applied to the wire 170 when the light-emitting device is deformed (e.g., warped).

In FIG. 25, an example in which the wire 170 connects the p-type pad electrode 118b of the LED chip 100c and the n-type pad electrode 118a of the LED chip 100d is illustrated. However, the present modification is not limited to this. The wire 170 may connect the p-type pad electrodes 118b or the n-type pad electrodes 118a of the adjacent LED chips 100c and 100d.

For example, as illustrated in FIG. 26, the wire 170 may connect the p-type pad electrode 118b of the LED chip 100c and the p-type pad electrode 118b of the LED chip 100d. In FIG. 26, the wire 170 is connected to the p-type pad electrode 118b of the LED chip 100c. The wire 170 penetrates the through-hole 154a formed through the LED chip 100c and is connected to the p-type pad electrode 118b of the adjacent LED chip 100d.

Thus, the p-type pad electrodes 118b of the adjacent LED chips 100c and 100d are connected to each other by the wire 170.

Note that the wire 170 may be connected to the n-type pad electrode 118a of the LED chip 100c, penetrate the through-hole 154a formed through the LED chip 100c, further penetrate the through-hole 154a of the adjacent LED chip 100d, and be connected to the n-type pad electrode 118a. Thus, the n-type pad electrodes 118a of the adjacent LED chips 100c and 100d are connected to each other by the wire 170.

In a case where the insulating wire 180 is used, the plurality of LED chips are fixed to each other by the insulating wire 180. It is therefore possible to obtain a fabric-like light-emitting device having high mechanical strength.

FIG. 27 is a top view illustrating a configuration of a light-emitting device according to the present modification.

As illustrated in FIG. 27, each of the LED chips 100c and 100d has a first through-hole 154a through which the wire 170 passes and a second through-hole 154b through which the insulating wire 180 passes. A distance between the second through-holes 154b of the adjacent LED chips 100c and 100d is shorter than that between the first through-holes 154a of the adjacent LED chips 100c and 100d. By thus changing the distance between the first through-holes 154a through which the wire 170 passes and the distance between the second through-holes 154b through which the insulating wire 180 passes, it is possible to adjust the mechanical strength of the light-emitting device. Moreover, by making the distance between the second through-holes 154b through which the insulating wire 180 passes shorter than that between the first through-holes 154a, it is possible to further reduce a load applied to the wires and a load applied to connection points between the wires and electrodes.

### Embodiment 5

Next, Embodiment 5 is described. A light-emitting device according to the present embodiment is different from the light-emitting devices described in Embodiments 1 through 4 in that through-holes provided through LED chips are arranged such that their diameters on a front surface of a substrate are different from those on a rear surface of the substrate.

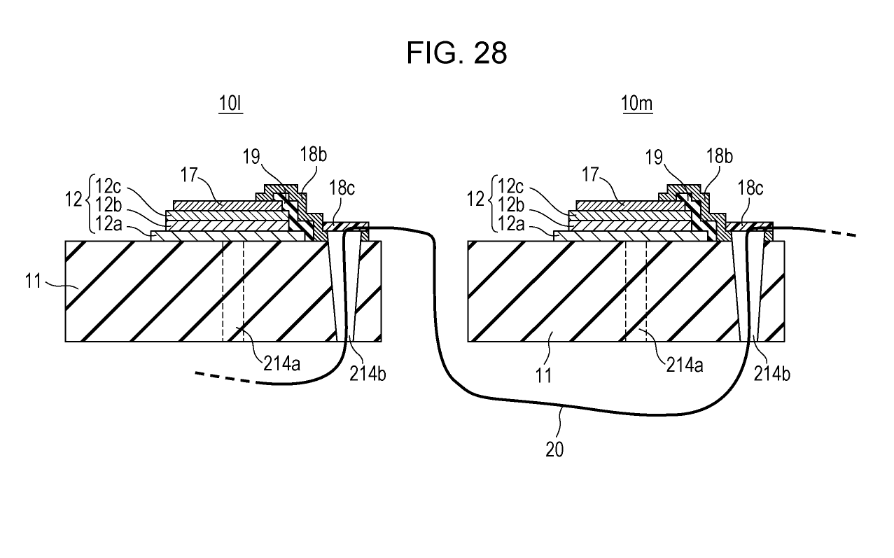

FIGS. 28 through 30 are cross-sectional views each illustrating configurations of LED chips of a light-emitting device according to the present embodiment.

As illustrated in FIG. 28, each of LED chips 10l and 10m includes a substrate 11, an n-type pad electrode (not illustrated), which is a cathode electrode, and a p-type pad electrode 18b, which is an anode electrode. In a light-emitting region 12, an n-type semiconductor layer 12a, an active layer 12b, and a p-type semiconductor layer 12c are stacked on the substrate 11. Through-holes 214a and 214b are formed through the substrate 11. A data line 20 penetrates the through-hole 214b and is connected to the p-type pad electrode 18b of the LED chip 10l by a conductive resin 18c. This data line 20 penetrates the through-hole 214b of the adjacent LED chip 10m and is connected to the p-type pad electrode 18b of the LED chip 10m by the conductive resin 18c.

The through-hole 214b is formed so that the diameter of the through-hole 214b on a surface closer to the p-type pad electrode 18b to which the data line 20 is connected, i.e., the front surface of the substrate 11 is larger than that on the rear surface of the substrate 11. By thus forming the through-hole 214b so that the diameter of the through-hole 214b on the surface closer to the p-type pad electrode 18b to which the data line 20 is connected is larger than that on the surface farther from the p-type pad electrode 18b, it is possible to suppress damage to the data line 20 caused by contact with the through-hole 214b.

The data line 20 may be connected to the n-type pad electrode 18a instead of the p-type pad electrode 18b. In this case, the through-hole 214a need just be formed so that the diameter of the through-hole 214a on a surface on which the n-type pad electrode 18a is formed is larger than that on a surface on which the n-type pad electrode 18a is not formed (the rear surface of the substrate 11 in FIG. 28).

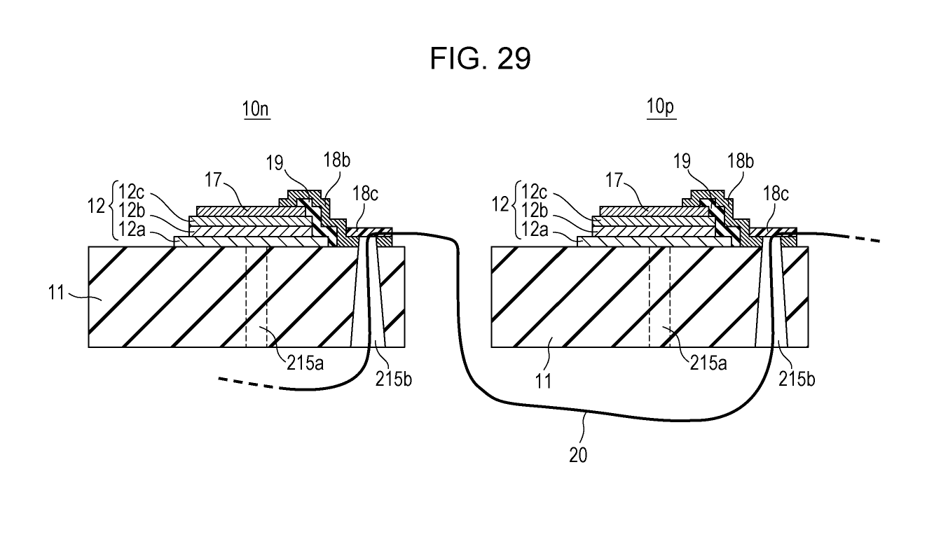

Each of LED chips 10n and 10p illustrated in FIG. 29 includes a substrate 11, an n-type pad electrode (not illustrated), and a p-type pad electrode 18b, as in the LED chips 10l and 10m illustrated in FIG. 28. Through-holes 215a and 215b are formed through the substrate 11. Furthermore, a data line 20 penetrates the through-hole 215b of the LED chip 10n and is connected to the p-type pad electrode 18b of the LED chip 10n by a conductive resin 18c. This data line 20 penetrates the through-hole 215b of the adjacent LED chip 10p and is connected to the p-type pad electrode 18b of the LED chip 10p by the conductive resin 18c.

The through-hole 215b is formed so that the diameter of the through-hole 215b on a surface closer to the p-type pad electrode 18b to which the data line 20 is connected, i.e., the front surface of the substrate 11 is smaller than that on the rear surface of the substrate 11. By thus forming the through-hole 215b so that the diameter of the through-hole 215b on the surface closer to the p-type pad electrode 18b to which the data line 20 is connected is smaller than that on the surface farther from the p-type pad electrode 18b, a movable range of the data line 20 is restricted. It is therefore possible to more effectively suppress a mechanical load applied to a connection point between the data line 20 and the p-type pad electrode 18b.

The data line 20 may be connected to the n-type pad electrode 18a instead of the p-type pad electrode 18b. In this case, the through-hole 215b need just be formed so that the diameter of the through-hole 215b on a surface on which the n-type pad electrode 18a is formed is smaller than that on a surface on which the n-type pad electrode 18a is not formed (the rear surface of the substrate 11 in FIG. 29).

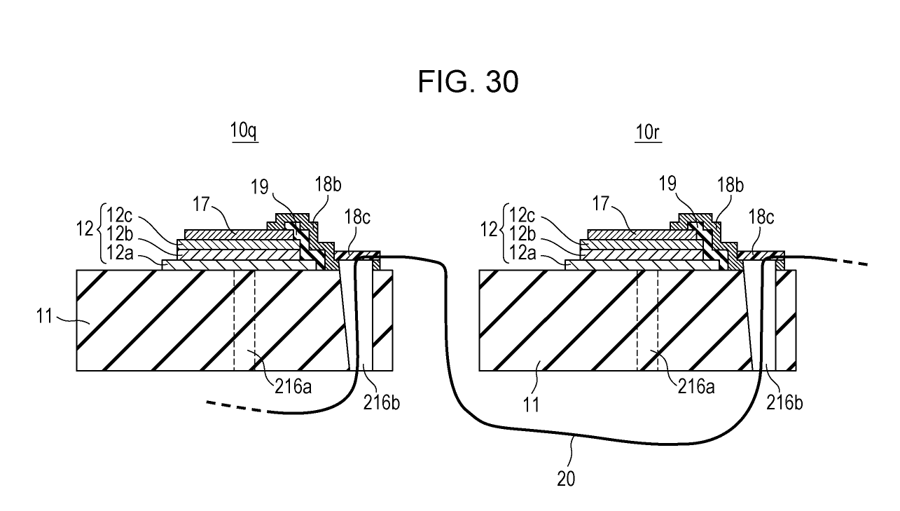

A further modification to FIGS. 28 and 29 is also possible. LED chips 10q and 10r illustrated in FIG. 30 are arranged such that inner surfaces of through-holes provided through the LED chips 10q and 10r are inclined towards the electrode side to which a wire passing through the through-holes is connected (the front surface side of the substrate 11 in FIG. 30). The arrangement other than the inclination of the through-holes is identical to that described with reference to FIGS. 28 and 29 and therefore is not explained repeatedly.

As illustrated in FIG. 30, in each of the adjacent LED chips 10q and 10r, an inner surface of a through-hole 216b is inclined towards the p-type pad electrode 18b side to which a data line 20 passing through the through-hole 216b is connected (the central side of the LED chips 10q and 10r). More specifically, the position of the inner surface of the through-hole 216b on one surface (top surface) on which the p-type pad electrode 18b to which the data line 20 passing through the through-hole 216b is connected is closer to the p-type pad electrode 18b side than the position of the inner surface on the other surface (bottom surface) opposite to the one surface out of two surfaces of the substrate 11 through which the through-hole 216b penetrates. By thus forming the through-hole 216b so that the inner surface of the through-hole 216b is inclined towards the p-type pad electrode 18b side (the central side of the LED chips 10q and 10r), the data line 20 is disposed in the through-hole 216b along such warped portion, so that a mechanical load applied to the data line 20 is small. Therefore, the data line 20 that passes through the through-hole 216b can be easily connected to the p-type pad electrode 18b.

The inclined inner surface of the through-hole 216b is not limited to the inner surface close to the p-type pad electrode 18b, but the whole inner surface of the through-hole 216b may be inclined towards the p-type pad electrode 18b side.

The data line 20 may be connected to an n-type pad electrode (not illustrated) instead of the p-type pad electrode 18b. In this case, by forming the through-hole 216a so that the inner surface of the through-hole 216a is inclined towards the n-type pad electrode, a wire 30 that passes through the through-hole 216a can be easily connected to the n-type pad electrode 18a.

Note that the connections illustrated in FIGS. 28 through 30 can be applied also to an address line 30 instead of the data line 20.

According to the light-emitting device according to the present embodiment, through-hoes provided through LED chips are formed so that the diameters of the through-holes on a front surface of a substrate are different from those on a rear surface of the substrate. It is therefore possible to reduce a load applied to connection points between wires and LED chips, thereby effectively suppressing breakage of the light-emitting device. Furthermore, by forming the through-holes in the LED chips so that the inner surfaces of the through-holes are inclined towards the electrode side, the wires are disposed in the through-hoes along such a warped portion, so that a mechanical load applied to the wires is small. Therefore, the wires passing through the through-holes can be easily connected to the electrodes.

### Modification of Embodiment 5

Next, a modification of Embodiment 5 is described. The light-emitting device according to the present embodiment is different from light-emitting device described in Embodiment 5 in that a substrate that constitute LED chips is a semiconductor substrate, and through-holes are formed through the semiconductor substrate.

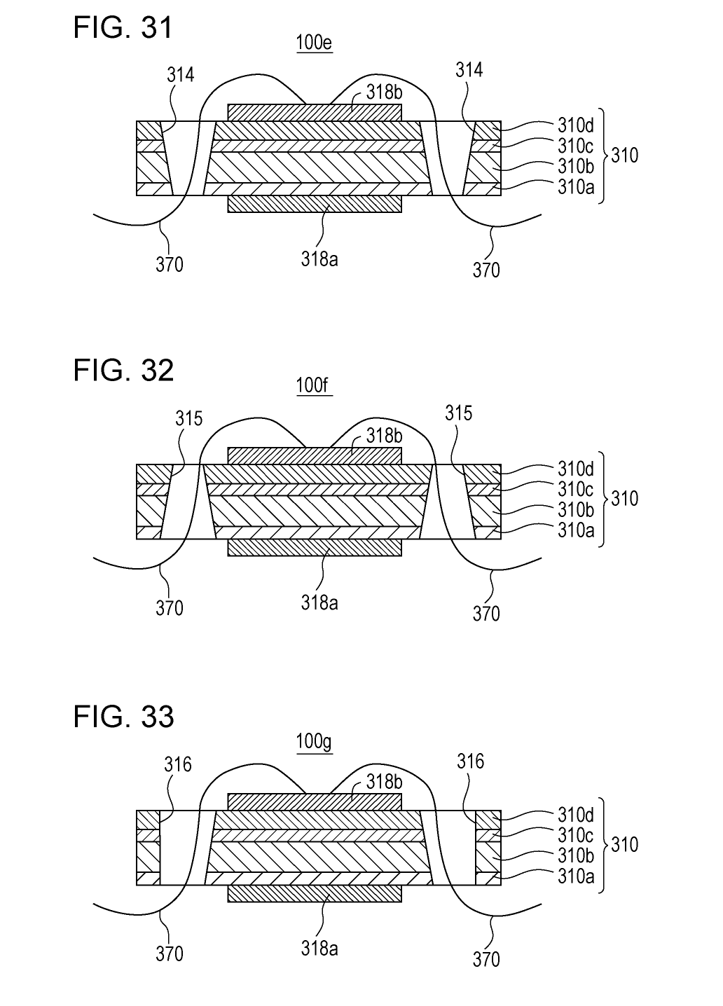

FIGS. 31 through 33 are cross-sectional views each illustrating a configuration of an LED chip of a light-emitting device according to the present embodiment.

As illustrated in FIG. 31, an LED chip 100e includes a substrate (multi-layer structure) 310, an n-type pad electrode 318a, which is a cathode electrode, and a p-type pad electrode 318b, which is an anode electrode. The substrate (multi-layer structure) 310 is arranged such that an n-type semiconductor layer 310b, an active layer 310c, a p-type semiconductor layer 310d are stacked on a conductive substrate 310a. Furthermore, a through-hole 314 is formed through the substrate (multi-layer structure) 310. Furthermore, a wire 370 (for example, a data line 20 or an address line 30) is connected to the p-type pad electrode 318b. The surface of the wire 370 is coated with an insulating film. The wire 370 penetrates the through-hole 314 and is connected to an electrode of an adjacent LED chip (not illustrated).

The through-hole 314 is formed so that the diameter of the through-hole 314 on a surface closer to the p-type pad electrode 318b to which the wire 370 is connected, i.e., the front surface of the substrate (multi-layer structure) 310 is connected is larger than that on the rear surface. By thus forming the through-hole 314 so that the diameter of the through-hole 314 on the surface closer to the p-type pad electrode 318b to which the wire 370 is connected is larger than that on the surface farther from the p-type pad electrode 318b, it is possible to suppress damage to the wire 370 caused by contact with the through-hole 314.

Note that it is unnecessary that the wire 370 be coated with an insulating film. In this case, it is only necessary that the inner surface of the through-hole 314 be coated with an insulating film. The wire 370 may be connected to the n-type pad electrode 318a instead of the p-type pad electrode 318b. In this case, the through-hole 314 need just be formed so that the diameter of the through-hole 314 on the surface on which the n-type pad electrode 318a is formed is larger.

As illustrated in FIG. 32, a through-hole 315 of an LED chip 100f may be formed so that the diameter of the through-hole 315 on a surface closer to a p-type pad electrode 318b to which a wire 370 is connected, i.e., the front surface of a substrate (multi-layer structure) 310 is smaller than that on the rear surface. By thus forming the through-hole 315 so that the diameter of the through-hole 315 on the surface closer to a p-type pad electrode 318b to which the wire 370 is connected is smaller than that on the surface farther from the p-type pad electrode 318b, a movable range of the wire 370 is restricted. It is therefore possible to more effectively suppress a mechanical load applied to a connection point between the wire 370 and the p-type pad electrode 318b.

Also in the arrangement of FIG. 32, it is unnecessary that the wire 370 be coated with an insulating film. In this case, it is only necessary that the inner surface of the through-hole 315 be coated with an insulating film, The wire 370 may be connected to the n-type pad electrode 318a instead of the p-type pad electrode 318b. In this case, the through-hole 315 need just be formed so that the diameter of the through-hole 315 on the surface on which the n-type pad electrode 318a is formed is smaller than that on the surface farther from the p-type pad electrode 318b.

According to the light-emitting devices illustrated in FIGS. 31 and 32, by forming through-holes in LED chips so that the diameters of the through-holes on the front surface of a substrate are different from those on the rear surface of the substrate, it is possible to reduce a load applied to connection points between wires and the LED chips, thereby effectively suppressing breakage of the light-emitting devices.

As illustrated in FIG. 33, an inner surface of a through-hole 316 provided through an LED chip 100g may be inclined towards a p-type pad electrode 318b to which a wire 370 passing through the through-hole 316 is connected.

The inner surface of the through-hole 316 is inclined towards the p-type pad electrode 318b side to which the wire 370 passing through the through-hole 316 is connected. More specifically, the position of the inner surface of the through-hole 316 on one surface (top surface) on which the p-type pad electrode 318b to which the wire 370 passing through the through-hole 316 is connected is closer to the p-type pad electrode 318b side than the position of the inner surface on the other surface (bottom surface) opposite to the one surface out of the two surface of the substrate 310 through which the through-hole 316 penetrates. By thus forming the through-hole 316 so that the inner surface of the through-hole 316 is inclined towards the p-type pad electrode 318b, the wire 370 is disposed in the through-hole 316 along such a warped portion, so that a mechanical load applied to the wire 370 is small. Therefore, the wire 370 passing through the through-hole 316 can be easily connected to the p-type pad electrode 318b.

The inclined inner surface of the through-hole 316 is not limited to the inner surface closer to the p-type pad electrode 318b, but the whole inner surface of the through-hole 316 may be inclined towards the p-type pad electrode 318b.

Furthermore, the wire 370 may be connected to the n-type pad electrode 318a instead of the p-type pad electrode 318b. In this case, by forming the through-hole 316 so that the inner surface of the through-hole 316 is inclined towards the n-type pad electrode 318a side, the wire 370 passing through the through-hole 316 can be easily connected to the n-type pad electrode 318a.

According to the light-emitting device according to the present embodiment, even in a case where a substrate that constitutes LED chips is a semiconductor substrate, by forming through-holes in the LED chips so that the diameters of the through-holes on the front surface of the substrate are different from those on the rear surface of the substrate, it is possible to reduce a load applied to connection points between the wires and the LED chips, thereby effectively suppressing breakage of the light-emitting device. Furthermore, by forming the through-holes in the LED chips so that the inner surfaces of the through-holes are inclined towards the electrode side, the wires are disposed in the through-holes along such a warped portion, so that a mechanical load applied to the wires is small. Therefore, the wires passing through the through-holes can be easily connected to the electrodes.

Note that the above embodiment are merely examples, and the present disclosure is not limited to the above embodiments.

For example, a substrate that constitutes LED chips may be a conductive substrate, an insulating substrate (insulator), or an n-type semiconductor substrate,

The insulating wires may pass through through-holes through which the wires (data lines and address lines) pass.

The number of through-holes is not limited to the number described in the above embodiments and can be changed to a different number. The diameter of a through-hole is not limited to the one described in the above embodiments and can be changed as appropriate. The shape of a through-hole is not limited to a specific one, but preferably has a shape that prevents a mechanical load being applied to a wire or an insulating wire that penetrates the through-hole.

Furthermore, a mask pattern used for patterning when forming elements of an LED chip is not limited to the one described in the above embodiments and may be a different pattern.

Furthermore, e, steps for producing a light-emitting device is not limited to the ones described above. The order of steps may be changed or another step may be added.

Furthermore, through-holes may be formed after formation of an n-type pad electrode and a p-type pad electrode of an LED chip or may be formed before formation of an n-type pad electrode and a p-type pad electrode of an LED chip.

Furthermore, a wire that penetrates a through-hole may be a wire having conductivity or may be an insulating wire having no conductivity. Furthermore, the way in which a wire or an insulating wire penetrates a through-hole may be changed as appropriate.

In the above description, a circuit in which wires are connected in a matrix manner has been described. Accordingly, an arrangement in which anodes (p-type semiconductor layers) are connected to each other and cathodes (n-type semiconductor layers) are connected to each other has been described. However, in all of the above embodiments, in a case where LED chips are connected linearly, an anode (p-type semiconductor layer) and a cathode (n-type semiconductor layer) may be connected to each other as illustrated in FIGS. 23 and 25.

Furthermore, the light-emitting device having the above feature may be also used as a display device. Therefore, even in a case where the light-emitting device is a display device used in such a manner that a wire substrate is curved, it is possible to reduce a load applied to a connection point between a conductor and a light-emitting device, thereby suppressing breakage of the light-emitting device.

The light-emitting devices according the above embodiments have been described so far, but the present disclosure is not limited to these embodiments. Various modifications to the above embodiments which a person skilled in the art can think of and any combination of constituent elements in different embodiments are encompassed within the scope of the present disclosure, unless such modifications and combinations are not deviated from the purpose of the present disclosure.

The light-emitting device according to the present disclosure can be used as a display device etc. that are warped in a curved shape.

What is claimed is:

1. A light-emitting device comprising:
a plurality of LED chips each having a light-emitting region, and a first electrode and a second electrode that are electrically connected to the light-emitting region;
a plurality of substrates each corresponding each of the plurality of LED chips, each of the plurality of the LED chips being provided above each of the plurality of substrates;
a plurality of through-holes each penetrating through each of the plurality of substrates; and
a plurality of wires each made of a conductive wire material,
wherein one of the plurality of the wires passes through a first through-hole penetrated through a first substrate of the plurality of the substrates and a second through-hole penetrated through a second substrate adjacent to the first substrate,
wherein the one of the plurality of the wires electrically connects the first electrode or the second electrode of a first LED chip corresponding to the first substrate, to the first electrode or the second electrode of a second LED chip corresponding to the second substrate.

2. The light-emitting device according to claim 1, wherein, at least part of a side surface of each of the plurality of the wires is not in contact with an inner surface of the first through-hole and an inner surface of the second through-hole.

3. The light-emitting device according to claim 1, wherein a first diameter of the through-hole on one of two surfaces of the substrate on which the first electrode and the second electrode are provided is smaller than a second diameter of the through-hole on the other one of the two surfaces of the substrate on which the first electrode and the second electrode are not provided.

4. The light-emitting device according to claim 1, wherein a first diameter of the through-hole on one of two surfaces of the substrate on which the first electrode and the second electrode are provided is larger than a second diameter of the through-hole on the other one of the two surfaces of the substrate on which the first electrode and the second electrode are not provided.

5. The light-emitting device according to claim 1, wherein, in a cross-sectional view, the shape of the through-hole in each of the plurality of substrates is tapered in the thickness direction of each of the plurality of substrates.

6. The light-emitting device according to claim 1, wherein each of the plurality of the wires is electrically connected the first electrode or the second electrode of the first LED chip, to the first electrode or the second electrode of the second LED chip, by a conductive material.

7. The light-emitting device according to claim 1, wherein the plurality of substrates include insulators.

8. The light-emitting device according to claim 1, further comprising a plurality of insulating wires, wherein:
one of the plurality of the insulating wires passes through the first through-hole and the second through-hole; and
the plurality of the insulating wires have higher rigidity than the plurality of the wires.

9. The light-emitting device according to claim 1, further comprising a plurality of insulating wires, wherein:
the first substrate has a third through-hole other than the first through-hole and the second substrate has a fourth through-hole other than the second through-hole;
one of the plurality of the insulating wires passes through the third through-hole penetrated through the first substrate and the fourth through-hole penetrated through the second substrate; and
the plurality of the insulating wires have higher rigidity than the plurality of the wires.

10. A light-emitting device comprising:
a plurality of LED chips each having a light-emitting region, a first electrode and a second electrode that are electrically connected to the light-emitting region, and a substrate in or on which the lighting-emitting region is provided;
a plurality of through-holes each penetrating through each of the plurality of the substrates; and
a plurality of wires each made of a threadlike conductive wire material,
wherein one of the plurality of the wires passes through a first through-hole penetrated through a first LED chip of the plurality of the LED chips and a second through-hole penetrated through a second LED chip of the plurality of the LED chips, the second LED chip being adjacent to the first LED chip, and electrically connects the first electrode or the second electrode of the first LED chip of the plurality of the LED chips to the first electrode or the second electrode of the second LED chip of the plurality of the LED chips.

11. The light-emitting device according to claim 10, wherein the first electrode and the second electrode are directly provided on the substrate.

12. The light-emitting device according to claim 10, wherein:
each of the plurality of LED chips comprises a multi-layer body in which an n-type semiconductor layer and a p-type semiconductor layer sandwiches the light-emitting region;
the first electrode is an anode electrode that is electrically connected to the p-type semiconductor layer;
the second electrode is a cathode electrode that is electrically connected to the n-type semiconductor layer; and
the through-hole penetrates through both surfaces of the substrate at a position where the through-hole is provided

13. The light-emitting device according to claim 10, wherein:
the substrate includes an n-type semiconductor layer;
a p-type semiconductor layer is stacked on the substrate;
the first electrode is an anode electrode that is electrically connected to the p-type semiconductor layer;
the second electrode is a cathode electrode that is electrically connected to the n-type semiconductor layer; and
the through-hole penetrates through both surfaces of the substrate at a position where the through-hole is provided.

14. The light-emitting device according to claim 10, wherein at least part of a side surface of each of the plurality of the wires is not in contact with the inner surface of the first through-hole and an inner surface of the second through-hole.

15. The light-emitting device according to claim 10, wherein a first diameter of the through-hole on one of two surfaces of the substrate on which the first electrode and the second electrode are provided is smaller than a second diameter of the through-hole on the other one of the two surfaces of the substrate on which the first electrode and the second electrode are not provided.

16. The light-emitting device according to claim 10, wherein a first diameter of the through-hole on one of two surfaces of the substrate on which the first electrode and the second electrode are provided is larger than a second diameter of the through-hole on the other one of the two surfaces of the substrate on which the first electrode and the second electrode are not provided.

17. The light-emitting device according to claim 10, wherein, in a cross-sectional view, the shape of the through-hole in each of the plurality of substrates is tapered in the thickness direction of each of the plurality of substrates.

18. The light-emitting device according to claim 10, wherein each of the plurality of the wires electrically connects the first electrode or the second electrode of the first LED chip, to the first electrode or the second electrode of the second LED chip, by a conductive material.

19. The light-emitting device according to claim 10, further comprising a plurality of insulating wires, wherein;
one of the plurality of the insulating wires passes through the first through-hole and the second through-hole; and
the plurality of the insulating wires have higher rigidity than the plurality of the wires.

20. The light-emitting device according to claim 10, further comprising a plurality of insulating wires, wherein:
the first LED chip has a third through-hole other than the first through-hole and the second LED chip has a fourth through-hole other than the second through-hole;
one of the plurality of the insulating wires passes through the third through-hole penetrated through the first LED chip and the fourth through-hole penetrated through the second LED chip; and
the plurality of the insulating wires have higher rigidity than the plurality of the wires.
